(19) United States
(12) Patent Application Publication
(10) Pub. No.: US 2025/0116935 A1
(43) Pub. Date: Apr. 10, 2025

(54) RADIATION-SENSITIVE RESIN COMPOSITION AND METHOD OF FORMING RESIST PATTERN

(71) Applicant: JSR CORPORATION, Tokyo (JP)

(72) Inventors: Daichi WATANABE, Tokyo (JP); Munehisa TOMIHAMA, Tokyo (JP); Katsuaki NISHIKORI, Tokyo (JP)

(73) Assignee: JSR CORPORATION, Tokyo (JP)

(21) Appl. No.: 18/906,361

(22) Filed: Oct. 4, 2024

Related U.S. Application Data
(63) Continuation of application No. PCT/JP2023/006294, filed on Feb. 21, 2023.

(30) Foreign Application Priority Data
Apr. 7, 2022 (JP) 2022-064089

(51) Int. Cl. G03F 7/039; C08F 212/14; C08F 220/18; C08F 220/22; G03F 7/00

(52) U.S. Cl. CPC G03F 7/0397; C08F 212/22; C08F 220/1807; C08F 220/1808; C08F 220/1809; C08F 220/1812; C08F 220/1818; C08F 220/22; G03F 7/70025; G03F 7/70033

(57) ABSTRACT

A radiation-sensitive resin composition includes: a first polymer and a compound. A solubility of the first polymer in a developer solution is capable of being altered by an action of an acid. The first polymer includes: a first structural unit containing a partial structure obtained by substituting a hydrogen atom of a carboxy group, a phenolic hydroxy group, or an amide group with a group represented by the following formula (1); and a second structural unit containing a phenolic hydroxy group. The compound includes: a monovalent radiation-sensitive onium cation containing an aromatic ring obtained by substituting at least one hydrogen atom with a fluorine atom or a fluorine atom-containing group; and a monovalent organic acid anion.

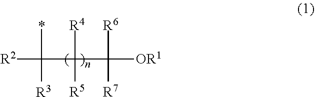

### CROSS-REFERENCE TO RELATED APPLICATIONS

The present application is a continuation application of International Patent Application No. PCT/JP2023/006294 filed Feb. 21, 2023, which claims priority to Japanese Patent Application No. 2022-064089 filed Apr. 7, 2022. The contents of these applications are incorporated herein by reference in their entirety.

### BACKGROUND OF THE DISCLOSURE

### Technical Field

The present disclosure relates to a radiation-sensitive resin composition and a method of forming a resist pattern.

### Discussion of the Background

A radiation-sensitive resin composition for use in microfabrication by lithography generates an acid at light-exposed regions upon an irradiation with a radioactive ray, e.g.: an electromagnetic wave such as a far ultraviolet ray such as an ArF excimer laser beam (wavelength of 193 nm) or a KrF excimer laser beam (wavelength of 248 nm), or an extreme ultraviolet ray (EUV) (wavelength of 13.5 nm); or a charged particle ray such as an electron beam. A chemical reaction in which the acid serves as a catalyst causes a difference between the light-exposed regions and light-unexposed regions in rates of dissolution in a developer solution, whereby a resist pattern is formed on a substrate.

Such radiation-sensitive resin compositions are required not only to have favorable sensitivity to exposure light such as the extreme ultraviolet ray and the electron beam, but also to result in superiority in terms of CDU (Critical Dimension Uniformity) performance, an ability to inhibit development defects, and the like.

To meet these requirements, types, molecular structures, and the like of polymers, acid generating agents, and other components which may be used in radiation-sensitive resin compositions have been investigated, and combinations thereof have been further investigated in detail (see Japanese Unexamined Patent Applications, Publication Nos. 2010-134279, 2014-224984, and 2016-047815).

### SUMMARY

One aspect of the disclosure is a radiation-sensitive resin composition containing: a first polymer (hereinafter, may be also referred to as “(A) polymer” or “polymer (A)”), solubility of which in a developer solution is capable of being altered by an action of an acid, the first polymer having: a first structural unit including a partial structure obtained by substituting a hydrogen atom of a carboxy group, a phenolic hydroxy group, or an amide group with a group represented by the following formula (1); and a second structural unit including a phenolic hydroxy group; and a compound (hereinafter, may be also referred to as “(Z) compound” or “compound (Z)”) having: a monovalent radiation-sensitive onium cation including an aromatic ring obtained by substituting at least one hydrogen atom with a fluorine atom or a fluorine atom-containing group; and a monovalent organic acid anion.

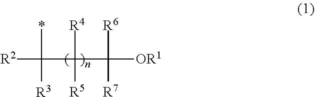

In the formula (1), R¹ represents a hydrogen atom or a monovalent organic group having 1 to 20 carbon atoms; R², R³, one or a plurality of R⁴s, one or a plurality of R⁵s, R⁶, and R⁷ each independently represent a substituted or unsubstituted monovalent hydrocarbon group having 1 to 20 carbon atoms, and optionally two groups among R², R³, one or a plurality of R⁴s, one or a plurality of R⁵s, R⁶, and R⁷ taken together represent an aliphatic ring having 4 to 20 ring atoms together with the carbon atom or the carbon chain to which the two groups bond, wherein in a case in which R⁶ or R⁷ represents the substituted monovalent hydrocarbon group having 1 to 20 carbon atoms, the hydrocarbon group has at least one hydrogen atom; n is an integer of 0 to 5; and * denotes a site of bonding to an ethereal oxygen atom of the carboxy group, an oxygen atom of the phenolic hydroxy group, or a nitrogen atom of the amide group.

An other aspect of the disclosure is a method of forming a resist pattern, the method including: applying the above-described radiation-sensitive resin composition directly or indirectly on a substrate to form a resist film; exposing the resist film; and developing the resist film exposed.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Along with further miniaturization of resist patterns, required levels for the aforementioned types of performance are further elevated, and there are demands for radiation-sensitive resin compositions capable of meeting the requirements described above.

The radiation-sensitive resin composition of an embodiment of the present disclosure is superior in sensitivity, and results in superiority in CDU performance and the ability to inhibit development defects. The method of forming a resist pattern of another embodiment of the present disclosure enables forming a resist pattern being superior in CDU performance and the ability to inhibit development defects, with high sensitivity. Therefore, these can be suitably used in manufacturing processes of semiconductor devices, in which further progress of miniaturization is expected in the future.

Hereinafter, the radiation-sensitive resin composition and the method of forming a resist pattern of embodiments of the present disclosure are described in detail.

### Radiation-Sensitive Resin Composition

The radiation-sensitive resin composition contains the polymer (A) and the compound (Z). The radiation-sensitive resin composition typically contains an organic solvent (hereinafter, may be also referred to as “(D) organic solvent” or “organic solvent (D)”). The radiation-sensitive resin composition may contain, as a favorable component, a radiation-sensitive acid generating agent (hereinafter, may be also referred to as “(B) acid-generating agent” or “acid-generating acid (B)”) other than the compound (Z). The radiation-sensitive resin composition may contain, as a favorable component, an acid diffusion control agent (hereinafter, may be also referred to as “(C) acid diffusion control agent” or “acid diffusion control agent (C)”) other than the compound (Z). The radiation-sensitive resin composition may contain, as a favorable component, a polymer (hereinafter, may be also referred to as “(F) polymer” or “polymer (F)”) having a percentage content of fluorine atoms which is higher than that of the polymer (A). The radiation-sensitive resin composition may contain, within a range not leading to impairment of the effects of the present invention, other optional component(s).

Due to the polymer (A) and the compound (Z) being contained, the radiation-sensitive resin composition is superior in sensitivity, and results in superiority in CDU performance and the ability to inhibit development defects. Although not necessarily clarified and without wishing to be bound by any theory, the reason for achieving the aforementioned effects by the radiation-sensitive resin composition due to involving such a constitution is presumed to be, for example, as in the following. Due to: the compound (Z) having superior acid-generating efficiency and consequently resulting in superior sensitivity and CDU performance; and to having the fluorine atom or the fluorine atom-containing group resulting in hydrophobicity of the compound (Z), which offsets hydrophilicity of the polymer (A), the compound (Z) is also superior in the ability to inhibit development defects. It is considered that as a result, the radiation-sensitive resin composition is superior in the sensitivity and the ability to inhibit development defects.

The radiation-sensitive resin composition may be prepared, for example, by mixing the polymer (A) and the compound (Z), as well as the acid generating agent (B), the acid diffusion control agent (C), the organic solvent (D), the polymer (E), and/or the other optional component(s), which is/are added as needed, in a certain ratio, and preferably filtering a thus resulting mixture through a membrane filter having a pore size of no greater than 0.2 μm.

Each component contained in the radiation-sensitive resin composition is described below.

### (A) Polymer

The polymer (A) has: a structural unit (hereinafter, may be also referred to as “structural unit (I)”) that includes a partial structure obtained by substituting a hydrogen atom of a carboxy group, a phenolic hydroxy group, or an amide group with a group (hereinafter, may be also referred to as “group (α)”) represented by the formula (1), described later; and a structural unit (hereinafter, may be also referred to as “structural unit (II)”) that includes a phenolic hydroxy group. The polymer (A) is a polymer, solubility of which in a developer solution is capable of being altered by an action of an acid. The radiation-sensitive resin composition may contain one, or two or more types of the polymer (A).

The polymer (A) may further have a structural unit (hereinafter, may be also referred to as “structural unit (III)”) including an acid-labile group (hereinafter, may be also referred to as “acid-labile group (b)”) other than the group (α). The polymer (A) may further have other structural unit(s) (hereinafter, may be also referred to merely as “other structural unit(s)”), aside from the structural units (I) to (III). The polymer (A) may have one, or two or more types of each structural unit.

The lower limit of a proportion of the polymer (A) in the radiation-sensitive resin composition with respect to total components other than the organic solvent (D) contained in the radiation-sensitive resin composition is preferably 50% by mass, more preferably 70% by mass, and still more preferably 80% by mass. The upper limit of the proportion is preferably 99% by mass, and more preferably 95% by mass.

The lower limit of a polystyrene equivalent weight average molecular weight (Mw) of the polymer (A) as determined by gel permeation chromatography (GPC) is preferably 1,000, more preferably 2,000 and still more preferably 3,000. The upper limit of the Mw is preferably 30,000, more preferably 20,000, and still more preferably 10,000. When the Mw of the polymer (A) falls within the above range, the coating characteristics of the radiation-sensitive resin composition can be improved. The Mw of the polymer (A) can be regulated by, for example, adjusting a type, usage amount, and/or the like of a polymerization initiator to be used in synthesis.

The upper limit of a ratio (hereinafter may be also referred to as “Mw/Mn” or “polydispersity index”) of the Mw to a polystyrene-equivalent number average molecular weight (Mn) of the polymer (A) as determined by GPC is preferably 2.5, more preferably 2.0, and still more preferably 1.7. The lower limit of the ratio is typically 1.0, preferably 1.1, more preferably 1.2, and still more preferably 1.3.

### Method of Measuring Mw and Mn

As referred to herein, the Mw and Mn of the polymer are values measured by using gel permeation chromatography (GPC) under the following conditions.

GPC columns: “G2000 HXL”×2, “G3000 HXL”×1, and “G4000 HXL”×1, available from Tosoh Corporation;
column temperature: 40° C.
elution solvent: tetrahydrofuran
flow rate: 1.0 mL/min
sample concentration: 1.0% by mass
amount of injected sample: 100 uL
detector: differential refractometer
standard substance: mono-dispersed polystyrene

The polymer (A) can be synthesized by, for example, polymerizing a monomer that gives each structural unit according to a well-known procedure.

Each structural unit contained in the polymer (A) is described below.

### Structural Unit (I)

The structural unit (I) is a structural unit including a partial structure obtained by substituting a hydrogen atom of a carboxy group, a phenolic hydroxy group, or an amide group with a group (the group (α)) represented by the following formula (1).

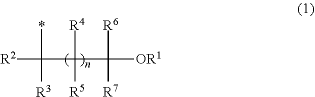

In the above formula (1), R¹ represents a hydrogen atom or a monovalent organic group having 1 to 20 carbon atoms; R², R³, one or a plurality of R⁴s, one or a plurality of R⁵s, R⁶, and R⁷ each independently represent a substituted or unsubstituted monovalent hydrocarbon group having 1 to 20 carbon atoms, or two of these groups taken together represent an aliphatic ring having 4 to 20 ring atoms together with the carbon atom or the carbon chain to which the two of these groups bond, wherein in a case in which R⁶ or R⁷ represents the substituted monovalent hydrocarbon group having 1 to 20 carbon atoms, the hydrocarbon group has at least one hydrogen atom; n is an integer of 0 to 5; and * denotes a site of bonding to an ethereal oxygen atom of the carboxy group, an oxygen atom of the phenolic hydroxy group, or a nitrogen atom of the amide group.

The polymer (A) may have one, or two or more types of the structural unit (I).

The group (α) is a group obtained by substituting a hydrogen atom contained in a carboxy group, a phenolic hydroxy group, or an amide group in the structural unit (I). In other words, the group (α) in the structural unit (I) is bonded to an ethereal oxygen atom in a carbonyloxy group, an oxygen atom in a phenolic hydroxy group, or a nitrogen atom in an amide group. The “phenolic hydroxy group” as referred to herein is not limited to a hydroxy group directly bonding to a benzene ring, and means any hydroxy group directly bonding to an aromatic ring in general. The “amide group” as referred to herein means a primary amide group represented by —CO—NH₂ or a secondary amide group represented by —CO—NHR.

In the case in which the group (α) is bonded to an ethereal oxygen atom of a carbonyloxy group or an oxygen atom of a phenolic hydroxy group, the group (α) is an acid-labile group. The “acid-labile group” as referred to means a group that substitutes for a hydrogen atom of a carboxy group, a hydroxy group, or the like, and is dissociated by an action of an acid to give a carboxy group, a hydroxy group, or the like. In this case, due to the polymer (A) having the structural unit (I), the property of altering the solubility in a developer solution by an action of an acid is exhibited. Furthermore, the group (α) is dissociated from the structural unit (I) by an action of an acid generated from the compound (Z), the acid generating agent (B), and/or the like by exposure, creating a difference in solubility in a developer solution of the polymer (A) between a light-exposed region and a light-unexposed region; accordingly, a resist pattern can be formed.

The number of “carbon atoms” as referred to herein means the number of carbon atoms constituting a group. The “valency” of a group means the number of atoms to which that group bonds. The “organic group” as referred to herein means a group that includes at least one carbon atom.

The “hydrocarbon group” encompasses both an “aliphatic hydrocarbon group” and an “aromatic hydrocarbon group”. The “aliphatic hydrocarbon group” encompasses both a “saturated hydrocarbon group” and an “unsaturated hydrocarbon group”. From a different viewpoint, the “aliphatic hydrocarbon group” encompasses both a “chain hydrocarbon group” and an “alicyclic hydrocarbon group”. The “chain hydrocarbon group” as referred to means a hydrocarbon group not including a ring structure but being constituted with only a chain structure, and encompasses both a linear hydrocarbon group and a branched hydrocarbon group. The “alicyclic hydrocarbon group” as referred to means a hydrocarbon group that includes, as a ring structure, not an aromatic ring but an aliphatic ring alone, and encompasses both a monocyclic alicyclic hydrocarbon group and a polycyclic alicyclic hydrocarbon group. In this regard, it is not necessary for the alicyclic hydrocarbon group to be constituted with only an aliphatic ring; a chain structure may be included in a part thereof. The “aromatic hydrocarbon group” as referred to means a hydrocarbon group that includes an aromatic ring as a ring structure. In this regard, it is not necessary for the aromatic hydrocarbon group to be constituted with only an aromatic ring; a chain structure or an aliphatic ring may be included in a part thereof.

The number of “ring atoms” means the number of atoms constituting a ring structure, and in a case of a polycyclic ring, the number of “ring atoms” means the number of atoms constituting the polycyclic ring. The “polycyclic ring” as referred to herein may encompass a spiro-type polycyclic ring in which two rings have one shared atom, a fused polycyclic ring in which two rings have two shared atoms, and a ring-assembled polycyclic ring in which two rings are connected by a single bond without having any shared atom. The “ring structure” encompasses an “aliphatic ring” and an “aromatic ring.” The “aliphatic ring” encompasses an “aliphatic hydrocarbon ring” and an “aliphatic heterocycle”. Of the aliphatic rings, polycyclic rings, encompassing an aliphatic hydrocarbon ring and an aliphatic heterocycle, fall under the “aliphatic heterocycle”. The “aromatic ring” encompasses an “aromatic hydrocarbon ring” and an “aromatic heterocycle”. Of the aromatic heterocycles, polycyclic rings, encompassing an aromatic hydrocarbon ring and an aromatic heterocycle, fall under the “aromatic heterocycle”.

The monovalent organic group having 1 to 20 carbon atoms is exemplified by: a monovalent hydrocarbon group having 1 to 20 carbon atoms; a group (hereinafter, may be also referred to as “group (α)”) that contains a divalent heteroatom-containing group between two adjacent carbon atoms of the monovalent hydrocarbon group; a group (hereinafter, may be also referred to as “group (β)”) obtained by substituting with a monovalent heteroatom-containing group, a part or all of hydrogen atoms included in the monovalent hydrocarbon group or the group (α); a group (hereinafter, may be also referred to as “group (γ)”) obtained by combining the monovalent hydrocarbon group, the group (α), or the group (β) with a divalent heteroatom-containing group; and the like.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include: alkyl groups such as a methyl group, an ethyl group, an n-propyl group, an i-propyl group, an n-butyl group, a sec-butyl group, an isobutyl group, and a tert-butyl group; alkenyl groups such as an ethenyl group, a propenyl group, a butenyl group, and a 2-methylprop-1-en-1-yl group; alkynyl groups such as an ethynyl group, a propynyl group, and a butynyl group; and the like.

Examples of the monovalent alicyclic hydrocarbon group having 3 to 20 carbon atoms include monocyclic alicyclic saturated hydrocarbon groups such as a cyclopentyl group and a cyclohexyl group; polycyclic alicyclic saturated hydrocarbon groups such as a norbornyl group, an adamantyl group, a tricyclodecyl group, and a tetracyclododecyl group; monocyclic alicyclic unsaturated hydrocarbon groups such as a cyclopentenyl group and a cyclohexenyl group; polycyclic unsaturated alicyclic hydrocarbon groups such as a norbornenyl group, a tricyclodecenyl group, and a tetracyclododecenyl group; and the like.

Examples of the monovalent aromatic hydrocarbon group having 6 to 20 carbon atoms include aryl groups such as a phenyl group, a tolyl group, a xylyl group, a naphthyl group, and an anthryl group; aralkyl groups such as a benzyl group, a phenethyl group, a naphthylmethyl group, and an anthrylmethyl group; and the like.

The heteroatom constituting the monovalent heteroatom-containing group or the divalent heteroatom-containing group is exemplified by an oxygen atom, a nitrogen atom, a sulfur atom, a phosphorus atom, a silicon atom, a halogen atom, and the like.

Examples of the monovalent heteroatom-containing group include a halogen atom, a hydroxy group, a carboxy group, a cyano group, an amino group, a sulfanyl group (—SH), an oxo group (═O), and the like. The halogen atom is a fluorine atom, a chlorine atom, a bromine atom, or an iodine atom.

The divalent heteroatom-containing group is exemplified by —O—, —CO—, —S—, —CS—, —NR′—, groups obtained by combination of at least two of these (for example, —COO—, —CONR′—, etc.), and the like. R′ represents a hydrogen atom or a monovalent hydrocarbon group having 1 to 10 carbon atoms. Examples of the monovalent hydrocarbon group having 1 to 10 carbon atoms represented by R′ include, among the groups exemplified above as the “monovalent hydrocarbon group having 1 to 20 carbon atoms”, those having 1 to 10 carbon atoms, and the like.

R¹ represents preferably a hydrogen atom.

The aliphatic ring having 4 to 20 ring atoms which may be represented by two selected from R², R³, one or a plurality of R⁴s, one or a plurality of R⁵s, R⁶, and R⁷ taken together, together with the carbon atom or the carbon chain to which these two bond, may be exemplified by: monocyclic saturated aliphatic rings such as a cyclobutene ring, a cyclopentane ring, and a cyclohexane ring; polycyclic saturated aliphatic rings such as a norbornane ring, an adamantane ring, a tricyclodecane ring, and a tetracyclododecane ring; monocyclic unsaturated aliphatic rings such as a cyclobutene ring, a cyclopentene ring, and a cyclohexene ring; polycyclic unsaturated aliphatic rings such as a norbornene ring, a tricyclodecene ring, and a tetracyclododecene ring; and the like.

In the case in which R², R³, one or a plurality of R⁴s, one or a plurality of R⁵s, R⁶, and R⁷ each represent a substituted or unsubstituted monovalent hydrocarbon group having 1 to 20 carbon atoms, the chain hydrocarbon group, the alicyclic hydrocarbon group, or the aromatic hydrocarbon group is preferred, an alkyl group, the monocyclic alicyclic saturated hydrocarbon group, or an aryl group is more preferred, and a methyl group, an ethyl group, an i-propyl group, a cyclopentyl group, or a phenyl group is still more preferred.

In the case in which two selected from R², R³, one or a plurality of R⁴s, one or a plurality of R⁵s, R⁶, and R⁷, taken together, represent the aliphatic ring having 4 to 20 ring atoms, together with the carbon atom or the carbon chain to which these two bond, the aliphatic ring is preferably the monocyclic saturated aliphatic ring, and more preferably a cyclopentane ring or a cyclohexane ring.

The two selected from R², R³, one or a plurality of R⁴s, one or a plurality of R⁵s, R⁶, and R⁷ taken together representing the aliphatic ring having 4 to 20 ring atoms together with the carbon atom or the carbon chain to which the two of these groups bond means that the two selected from R², R³, one or a plurality of R⁴s, one or a plurality of R⁵s, R⁶, and R⁷ taken together represent the aliphatic ring, and has a meaning of excluding a case in which three or more selected from R², R³, one or a plurality of R⁴s, one or a plurality of R⁵s, R⁶, and R⁷ taken together represent the aliphatic ring.

For example, a group represented by the following formula (m1) corresponds to a case in which n is 3 in the above formula (1), but since two R⁴s and two R⁵s, being a total of four groups, represent an adamantane structure together with the carbon chain to which these bond, this is not equivalent to the group (α). Furthermore, a group represented by the following formula (m2) corresponds to a case in which n is 1 in the above formula (1), but since R², R³, R⁶, and R⁷, being a total of four groups, represent an adamantane structure together with the carbon chain to which these bond, this is not equivalent to the group (α).

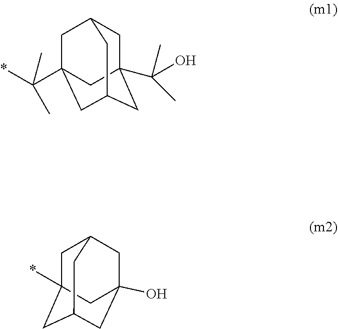 [SMILES: *C(C)(C)C12CC3CC(C1)CC(C(C)(C)O)(C3)C2 ; *C12CC3CC(C1)CC(O)(C3)C2]

A part or all of hydrogen atoms contained in the hydrocarbon group which may be represented by R², R³, one or a plurality of R⁴s, one or a plurality of R⁵s, R⁶, or R⁷ may be substituted with a substituent. Examples of the substituent include: halogen atoms such as a fluorine atom and an iodine atom; a carboxy group; a cyano group; a nitro group; an alkoxy group; an alkoxycarbonyl group; an alkoxycarbonyloxy group; an acyl group; an acyloxy group; an oxo group (═O); and the like. However, in a case in which R⁶ or R⁷ represents a substituted monovalent hydrocarbon group having 1 to 20 carbon atoms, the hydrocarbon group has at least one hydrogen atom. In other words, in the case in which R⁶ or R⁷ represents a substituted monovalent hydrocarbon group having 1 to 20 carbon atoms, a part of the hydrogen atoms contained in the hydrocarbon group are substituted with the substituent.

n is preferably 0 to 2, more preferably 0 or 1, and still more preferably 0.

The group (α) is preferably a group represented by one of the following formulae (a-1) to (a-9).

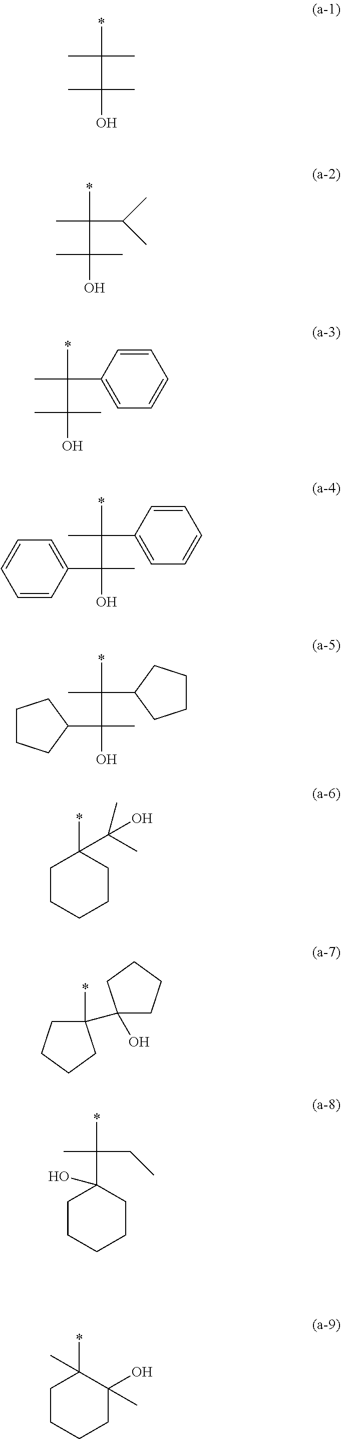

In the above formulae (a-1) to (a-9), * is as defined in the above formula (1).

Examples of the structural unit (I) include structural units represented by the following formulae (3-1) to (3-3).

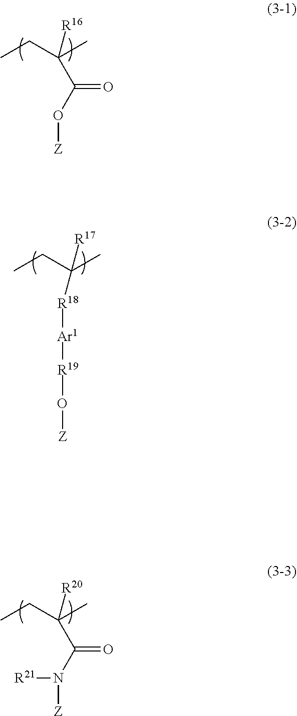

In the above formulae (3-1) to (3-3), Z represents the group (the group (α)) represented by the above formula (1).

In the above formula (3-1), R¹⁶ represents a hydrogen atom, a fluorine atom, a methyl group, or a trifluoromethyl group.

In the above formula (3-2), R¹⁷ represents a hydrogen atom or a methyl group; R¹⁸ represents a single bond, an oxygen atom, —COO—, or —CONH—; Ar¹ represents a group obtained by removing two hydrogen atoms from a substituted or unsubstituted aromatic hydrocarbon ring having 6 to 30 ring atoms; and R¹⁹ represents a single bond or —CO—.

In the above formula (3-3), R²⁰ represents a hydrogen atom, a fluorine atom, a methyl group, or a trifluoromethyl group; and R²¹ represents a hydrogen atom or a monovalent organic group having 1 to 20 carbon atoms.

In light of copolymerizability of a monomer that gives the structural unit (I), R¹⁶ represents preferably a hydrogen atom or a methyl group, and more preferably a methyl group.

Examples of the aromatic hydrocarbon ring having 6 to 30 ring atoms which gives Ar¹ include: a benzene ring; fused polycyclic aromatic hydrocarbon rings such as a naphthalene ring, an anthracene ring, a fluorene ring, a biphenylene ring, a phenanthrene ring, and a pyrene ring; ring-assembled aromatic hydrocarbon rings such as a biphenyl ring, a terphenyl ring, a binaphthalene ring, and a phenylnaphthalene ring; and the like.

The structural unit (I) is preferably the structural unit (I). In other words, the structural unit (I) is preferably a structural unit which includes a partial structure obtained by substituting a hydrogen atom in a carboxy group with the group (α).

The lower limit of a proportion of the structural unit (I) in the polymer (A) contained with respect to total structural units constituting the polymer (A) is preferably 0.5 mol %, more preferably 1 mol %, and still more preferably 5 mol %. The upper limit of the proportion is preferably 30 mol %, more preferably 20 mol %, and still more preferably 15 mol %. When the proportion of the structural unit (I) falls within the above range, the sensitivity, the CDU performance, and the ability to inhibit development defects resulting from the radiation-sensitive resin composition can be further improved. With regard to upper limits and lower limits of numerical value ranges in the present specification, unless otherwise specified particular, upper limits may mean “no greater than” or “less than,” and lower limits may mean “no less than” or “greater than”. Furthermore, upper limit values and lower limit values may be combined ad libitum.

The polymer (A) having the structural unit (I) can be synthesized by polymerizing a monomer (hereinafter, may be also referred to as “(X) monomer” or “monomer (X)”) that gives the structural unit (I) by a well-known procedure. The monomer (X) can be obtained by, for example, synthesizing: a diol compound that gives the group (α), such as pinacol; and a compound which becomes a skeletal structure of the monomer (X), such as chloride methacrylate.

### Structural Unit (II)

The structural unit (II) is a structural unit that includes a phenolic hydroxy group. The polymer (A) may include one, or two or more types of the structural unit (II).

In a case of conducting a KrF exposure, an EUV exposure, or an electron beam exposure, the sensitivity of the radiation-sensitive resin composition can be further enhanced due to the polymer (A) having the structural unit (II). Therefore, the radiation-sensitive resin composition can be suitably used as a radiation-sensitive resin composition for the KrF exposure, the EUV exposure, or the electron beam exposure.

Examples of the structural unit (II) include a structural unit (hereinafter, may be also referred to as “structural unit (II-1)”) represented by the following formula (II-1), and the like.

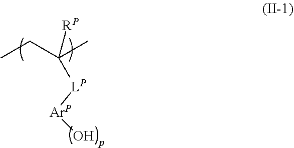

In the above formula (II-1), R^{P} represents a hydrogen atom, a fluorine atom, a methyl group, or a trifluoromethyl group; L^{P} represents a single bond, —COO—, —O—, or —CONH—; Ar^{P} represents a group obtained by removing (p+1) hydrogen atoms from a substituted or unsubstituted aromatic hydrocarbon ring having 6 to 30 ring atoms; and p is an integer of 1 to 3.

A “group obtained by removing X hydrogen atoms from a ring structure” as referred to means a group obtained by removing X hydrogen atoms bonding to an atom constituting a ring structure.

In light of a degree of copolymerization of a monomer that gives the structural unit (II-1), R^{P} represents preferably a hydrogen atom.

L^{P} represents preferably a single bond.

Examples of the aromatic hydrocarbon ring structure having 6 to 30 ring atoms which gives Ar^{P} include those similar to the ring structures exemplified as the aromatic hydrocarbon ring structure having 6 to 30 ring atoms which gives Ar¹ in the above formula (3-2), and the like. Of these, a benzene structure or a naphthalene structure is preferred.

A part or all of hydrogen atoms in the aromatic hydrocarbon ring may be substituted with a substituent. Examples of the substituent include groups similar to those exemplified as the substituent which may be contained in, e.g., R² in the above formula (1), and the like. Of these, a fluorine atom is preferred.

p is preferably 1.

Examples of the structural unit (II-1) include structural units (hereinafter, may be also referred to as “structural units (II-1-1) to (II-1-18)”) represented by the following formulae (II-1-1) to (II-1-18).

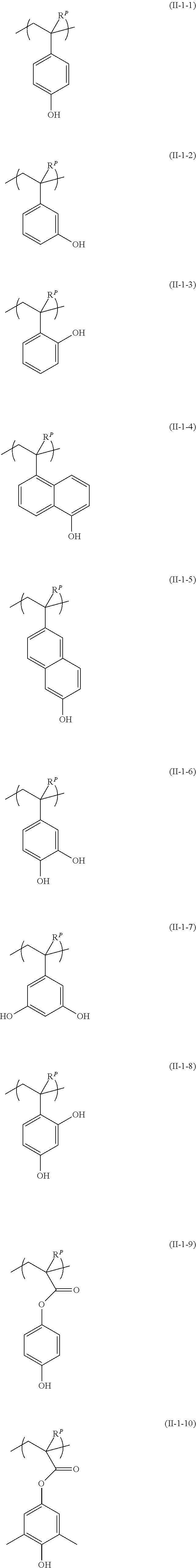

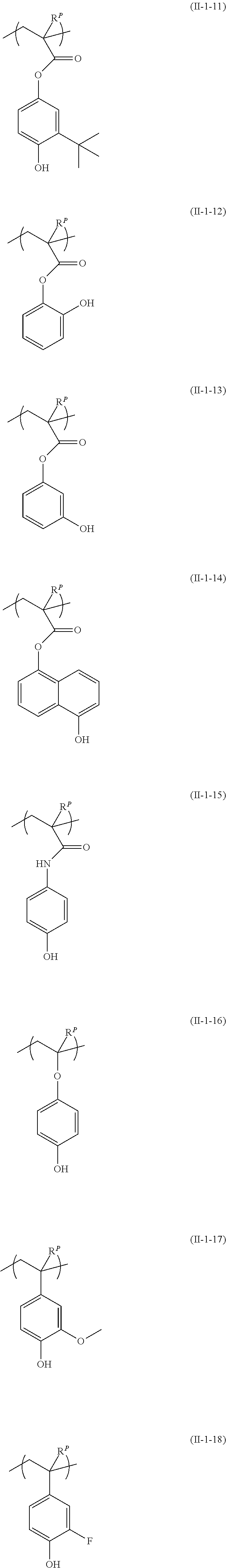

In the above formulae (II-1-1) to (II-1-18), R¹ is as defined in the above formula (II-1).

The structural unit (II-1) is preferably the structural unit (II-1-1) to (II-1-3), (II-1-5) to (II-1-9), (II-1-12) to (II-1-13), or (II-1-18), or a combination thereof, more preferably the structural unit (II-1-1) to (II-1-3), (II-1-5), (II-1-9), (II-1-12) to (II-1-13), or (II-1-18) or a combination thereof, and still more preferably a combination of the structural unit (II-1-1) and the structural unit (II-1-2), (II-1-5), or (II-1-18). In this case, the CDU performance resulting from the radiation-sensitive resin composition can be further improved.

The lower limit of a proportion of the structural unit (II) in the polymer (A) contained with respect to the total structural units constituting the polymer (A) is preferably 10 mol %, and more preferably 20 mol %. The upper limit of the proportion is preferably 60 mol %, and more preferably 50 mol %.

Examples of a monomer that gives the structural unit (II) include a monomer obtained by substituting a hydrogen atom in a phenolic hydroxy group (—OH) such as 4-acetoxystyrene or 3,5-diacetoxystyrene with an acetyl group or the like. In this case, the polymer (A) having the structural unit (II) can be synthesized by, for example, polymerizing the monomer, and then carrying out a hydrolysis reaction on a polymerization reaction product thus obtained, in the presence of a base such as an amine.

### Structural Unit (III)

The structural unit (III) includes an acid-labile group (hereinafter, may be also referred to as “(b) acid-labile group” or “acid-labile group (b)”) other than the group (α). More specifically, the structural unit (III) is a structural unit including a partial structure obtained by substituting a hydrogen atom in a carboxy group or a phenolic hydroxy group with the acid-labile group (b). The structural unit (III) is a structural unit which is different from the structural unit (I). The polymer (A) may have one, or two or more types of the structural unit (III).

In the case in which the polymer (A) has the structural unit (III), the acid-labile group (b) is dissociated from the structural unit (III) by an action of an acid generated from the compound (Z), the acid generating agent (B), and/or the like, enabling adjusting a difference in solubility in a developer solution of the polymer (A) between a light-exposed region and a light-unexposed region.

The acid-labile group (b) is a group obtained by substituting a hydrogen atom contained in the carboxy group or the phenolic hydroxy group in the structural unit (III). In other words, the acid-labile group (b) in the structural unit (III) is bonded to the ethereal oxygen atom in the carbonyloxy group or to the oxygen atom in the phenolic hydroxy group.

The acid-labile group (b) is not particularly limited as long as it is a group other than the group (α), and examples thereof include groups (hereinafter, may be also referred to as “acid-labile groups (b-1) to (b-3)”) represented by the following formulae (b-1) to (b-3), and the like.

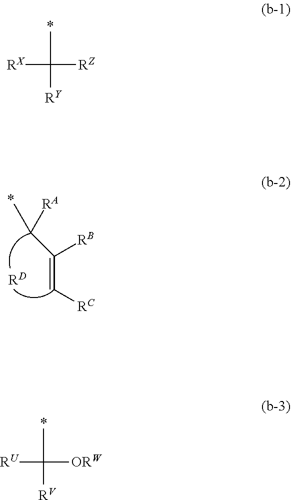

In the above formulae (b-1) to (b-3), * denotes a site bonding to the ethereal oxygen atom in the carbonyloxy group or to the oxygen atom in the phenolic hydroxy group.

In the above formula (b-1), R^{X} represents a substituted or unsubstituted monovalent hydrocarbon group having 1 to 20 carbon atoms; and R^{Y} and R^{Z} each independently represent a monovalent hydrocarbon group having 1 to 20 carbon atoms, or R^{Y} and R^{Z} taken together represent a saturated aliphatic ring having 3 to 20 ring atoms, together with the carbon atom to which R^{Y} and R^{Z} bond.

In the above formula (b-2), R^{A} represents a hydrogen atom; R^{B} and R^{C} each independently represent a hydrogen atom or a monovalent hydrocarbon group having 1 to 20 carbon atoms; and R^{D} represents a divalent hydrocarbon group having 1 to 20 carbon atoms constituting an unsaturated aliphatic ring having 4 to 20 ring atoms, together with the carbon atom to which each of R^{A}, R^{B}, and R^{C} bonds.

In the above formula (b-3), R^{U} and R^{V} each independently represent a hydrogen atom or a monovalent hydrocarbon group having 1 to 20 carbon atoms, and R^{W} represents a monovalent hydrocarbon group having 1 to 20 carbon atoms, or R^{U} and R^{V} taken together represent an aliphatic having 3 to 20 ring atoms together with the carbon atom to which R^{U} and R^{V} bond, or R^{U} and R^{W} taken together represent an aliphatic heterocycle having 4 to 20 ring atoms together with the carbon atom to which R^{U} bonds and the oxygen atom to which R^{W} bonds.

Examples of the monovalent hydrocarbon group having 1 to 20 carbon atoms which may be represented by R^{X}, R^{Y}, R^{Z}, R^{B}, R^{C}, R^{U}, R^{V}, or R^{W} include groups similar to those exemplified as the monovalent hydrocarbon group having 1 to 20 carbon atoms which may be represented by R² or the like in the above formula (1), and the like.

Examples of the substituent which may be contained in the hydrocarbon group represented by R^{X} include groups similar to those exemplified as the substituent which may be contained in the R² or the like in the above formula (1), and the like.

Examples of the saturated aliphatic ring having 3 to 20 ring atoms which may be constituted by R^{Y} and R^{Z} taken together, together with the carbon atom to which R^{Y} and R^{Z} bond, and of the aliphatic ring having 3 to 20 ring atoms which may be constituted by R^{U} and R^{V} taken together, together with the carbon atom to which R^{U} and R^{V} bond, include a cyclopropane ring, and the aliphatic ring having 4 to 20 ring atoms exemplified in the above formula (1).

Examples of the divalent hydrocarbon group having 1 to 20 carbon atoms represented by R^{D} include groups obtained by removing one hydrogen atom from the groups exemplified as the monovalent hydrocarbon group having 1 to 20 carbon atoms which may be represented by R^{X}, R^{Y}, R^{Z}, R^{B}, R^{C}, R^{U}, R^{V}, or R^{W}, described above; and the like.

Examples of the unsaturated aliphatic ring having 4 to 20 ring atoms represented by R^{D}, together with the carbon atom to which each of R^{A}, R^{B}, and R^{C} bond, include monocyclic unsaturated aliphatic rings such as a cyclobutene ring, a cyclopentene ring, and a cyclohexene ring; polycyclic unsaturated aliphatic rings such as a norbornene ring; and the like.

Examples of the aliphatic heterocycle having 4 to 20 ring atoms which may be represented by R^{U} and R^{W} taken together, together with the carbon atom to which R^{U} bonds and the oxygen atom to which R^{W} bonds include saturated oxygen-containing heterocycles such as an oxacyclobutane ring, an oxacyclopentane ring, and an oxacyclohexane ring; unsaturated oxygen-containing heterocycles such as an oxacyclobutene ring, an oxacyclopentene ring, and an oxacyclohexene ring; and the like.

In the case in which each of R^{Y} and R^{Z} represents the monovalent hydrocarbon group having 1 to 20 carbon atoms, each of R^{Y} and R^{Z} represents preferably the chain hydrocarbon group, more preferably an alkyl group, and still more preferably a methyl group or an ethyl group. R^{X} in this case represents preferably the alicyclic hydrocarbon group or the aromatic hydrocarbon group, more preferably the monocyclic alicyclic saturated hydrocarbon group or an aryl group, and still more preferably a cyclohexyl group, a phenyl group, or a naphthyl group. In this case, the substituent contained in R^{X} is preferably a halogen atom, and more preferably a fluorine atom or an iodine atom.

In the case in which R^{Y} and R^{Z} taken together represent the saturated aliphatic ring having 3 to 20 ring atoms together with the carbon atom to which R^{Y} and R^{Z} bond, the saturated aliphatic ring is preferably the monocyclic saturated aliphatic ring or the polycyclic saturated aliphatic ring, and more preferably a cyclopentane ring, a cyclohexane ring, or an adamantane ring. R^{X} in this case represents preferably a chain hydrocarbon group or an aromatic hydrocarbon group, more preferably an alkyl group or a phenyl group, and still more preferably a methyl group, an ethyl group, an i-propyl group, or a phenyl group. In this case, the substituent contained in R^{X} is preferably a halogen atom, and more preferably an iodine atom.

R^{B} represents preferably a hydrogen atom.

R^{C} represents preferably a hydrogen atom or a chain hydrocarbon group, more preferably a hydrogen atom or the alkyl group, and still more preferably a methyl group.

The unsaturated aliphatic ring having 4 to 20 ring atoms represented by R^{D}, together with the carbon atom to which each of R^{A}, R^{B}, and R^{C} bond is preferably the monocyclic unsaturated aliphatic ring, and more preferably a cyclohexene ring.

The acid-labile group (b) is preferably the acid-labile group (b-1) or (b-2).

Examples of the acid-labile group (b-1) include groups represented by the following formulae (b-1-1) to (b-1-10). Examples of the acid-labile group (b-2) include groups represented by the following formula (b-2-1).

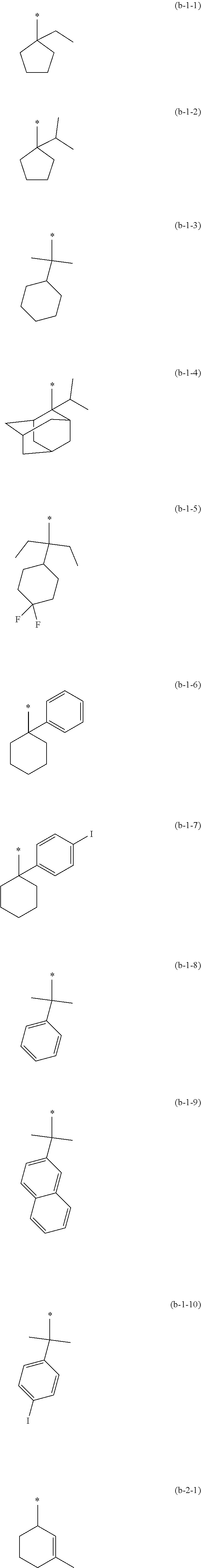

In the above formulae (b-1-1) to (b-1-10) and (b-2-1), * is as defined in the above formulae (b-1) and (b-2).

Examples of the structural unit (III) include structural units (hereinafter, may be also referred to as “structural unit (III-1) or (III-2)”) represented by the following formula (III-1) or (III-2).

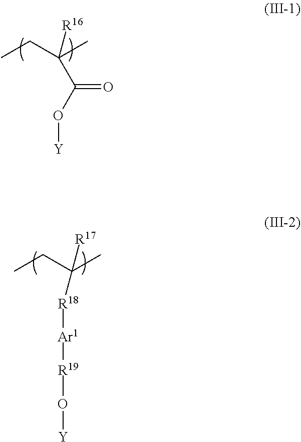

In the above formulae (III-1) and (III-2), Y represents the group (the acid-labile group (b)) represented by the above formulae (b-1) to (b-3).

In the above formula (III-1), R¹⁶ is as defined in the above formula (3-1). In the above formula (III-2), R¹⁷, R¹⁸, Ar¹, and R¹⁹ are as defined in the above formula (3-2).

The structural unit (III) is preferably the structural unit (III-1).

In the case in which the polymer (A) has the structural unit (III), the lower limit of a proportion of the structural unit (III) in the polymer (A) with respect to the total structural units constituting the polymer (A) is preferably 20 mol %, and more preferably 30 mol %. The upper limit of the proportion is preferably 70 mol %, and more preferably 60 mol %.

### Other Structural Unit(s)

The other structural unit(s) is/are structural unit(s) aside from the structural units (I) to (III). The other structural unit(s) may be exemplified by a structural unit including a lactone structure, a cyclic carbonate structure, a sultone structure, or a combination thereof; a structural unit including an alcoholic hydroxy group; and the like.

### (Z) Compound

The compound (Z) is a compound having: a monovalent radiation-sensitive onium cation (hereinafter, may be also referred to as “cation (P)”) including an aromatic ring obtained by substituting at least one hydrogen atom with a fluorine atom or a fluorine atom-containing group; and a monovalent organic acid anion (hereinafter, may be also referred to as “anion (Q)”). The radiation-sensitive resin composition may contain one, or two or more types of the compound (Z).

Depending on the type of the anion group, described later, included in the anion (Q), the compound (Z) has: an effect of generating an acid upon irradiation with a radioactive ray in the radiation-sensitive resin composition; or an effect of inhibiting an undesired chemical reaction (for example, a dissociation reaction of the acid-labile group) in light-unexposed regions by controlling a phenomenon in which an acid generated from the acid-generating agent (B) and/or the like upon exposure is diffused in the resist film. In other words, depending on the type of the anion group, the compound (Z) functions as a radiation-sensitive acid-generating agent or an acid diffusion control agent (quencher) in the radiation-sensitive resin composition.

In the case in which the compound (Z) functions as the radiation-sensitive acid generating agent, the radioactive ray may be exemplified by radioactive rays similar to those exemplified as the exposure light in the exposing in the method of forming a resist pattern of an other embodiment of the present disclosure, described later. The group (α) included in the structural unit (I) which is contained in the polymer (A), or the like is dissociated by an action of an acid generated from the compound (Z) upon irradiation with the radioactive ray, whereby a carboxy group, a phenolic hydroxy group, and/or the like are/is generated to create a difference in solubility of the resist film in the developer solution between light-exposed regions and light-unexposed regions; accordingly, a resist pattern can be formed.

In the case in which the compound (Z) functions as the acid diffusion control agent, an acid is generated in the light-exposed regions to increase the solubility or insolubility of the polymer (A) in the developer solution, and a superior acid-trapping function by the anion is exhibited, functioning as a quencher in the light-unexposed regions, whereby acid diffused from the light-exposed regions is trapped. Thus, the compound (Z) can enhance roughness at interfaces between the light-exposed regions and the light-unexposed regions, and improve the resolution by enhancing the contrast between the light-exposed regions and the light-unexposed regions.

Despite the aforementioned effect of the compound (Z) in the radiation-sensitive resin composition, described above, it is considered that containing the compound (Z) in the radiation-sensitive resin composition is a factor in the radiation-sensitive resin composition exhibiting superiority in sensitivity, and resulting in superiority in the CDU performance and the ability to inhibit development defects.

In the case in which the compound (Z) functions as the radiation-sensitive acid-generating agent, the lower limit of a content of the compound (Z) in the radiation-sensitive resin composition is, with respect to 100 parts by mass of the polymer (A), preferably 1 part by mass, more preferably 5 parts by mass, and still more preferably 10 parts by mass. The upper limit of the content is preferably 50 parts by mass, more preferably 40 parts by mass, and still more preferably 30 parts by mass.

In the case in which the compound (Z) functions as the acid diffusion control agent, the lower limit of a proportion of the compound (Z) in the radiation-sensitive resin composition acid with respect to 100 mol % of the radiation-sensitive acid generating agent (the compound (Z) functioning as the radiation-sensitive acid generating agent, and/or the acid generating agent (B)) contained in the radiation-sensitive resin composition is preferably 10 mol %, more preferably 20 mol %, and still more preferably 30 mol %. The upper limit of the proportion is preferably 60 mol %, more preferably 50 mol %, and still more preferably 40 mol %.

Each structure contained in the polymer (Z) is described below.

### Cation (P)

The cation (P) is a monovalent radiation-sensitive onium cation. The cation (P) includes an aromatic ring (hereinafter, may be also referred to as “aromatic ring (p)”) obtained by substituting at least one hydrogen atom with a fluorine atom or a fluorine atom-containing group. It is considered that the cation (P) including the aromatic ring (p) is a factor in the radiation-sensitive resin composition exhibiting superior sensitivity, and resulting in superiority in the CDU performance and the ability to inhibit development defects.

The aromatic ring (p) may be exemplified by an aromatic hydrocarbon ring having 6 to 20 ring atoms, an aromatic heterocycle having 5 to 30 ring atoms, and the like.

Examples of the aromatic hydrocarbon ring having 6 to 30 ring atoms include those similar to those exemplified as the aromatic hydrocarbon ring structure having 6 to 30 ring atoms which gives Ar¹ in the above formula (3-2), and the like.

Examples of the aromatic heterocycle having 5 to 30 ring atoms include: oxygen atom-containing heterocycles such as a furan ring, a pyran ring, a benzofuran ring, and a benzopyran ring; nitrogen atom-containing heterocycles such as a pyrrole ring, a pyridine ring, a pyrimidine ring, an indole ring, and a quinolone ring; sulfur atom-containing heterocycles such as a thiophene ring and a dibenzothiophene ring; and the like.

The aromatic ring (p) is preferably the aromatic hydrocarbon ring having 6 to 30 ring atoms or the aromatic heterocycle having 5 to 30 ring atoms, more preferably a benzene ring, a ring-assembled aromatic hydrocarbon ring, or a sulfur atom-containing heterocycle, and still more preferably a benzene ring, a naphthalene ring, or a dibenzothiophene ring.

The aromatic ring (p) is obtained by substituting at least one hydrogen atom which bonds to an atom constituting the aromatic ring (p) with a fluorine atom or a fluorine atom-containing group. The “fluorine atom-containing group” as referred to means a group having at least one fluorine atom. Examples of the fluorine atom-containing group include a group (hereinafter, may be also referred to as “fluorinated hydrocarbon group”) obtained by substituting a part or all of hydrogen atoms in a monovalent hydrocarbon group having 1 to 20 carbon atoms with a fluorine atom, and the like. The fluorine atom-containing group is preferably a fluorinated alkyl group, and more preferably a trifluoromethyl group.

The number of substitutions with a fluorine atom or a fluorine atom-containing group in the aromatic ring (p) is no less than 1. The number of substitutions is preferably 1 to 3, and more preferably 1 or 2.

Furthermore, substitution of a hydrogen atom which bonds to an atom constituting the aromatic ring (p) may be carried out with a substituent other than a fluorine atom or a fluorine atom-containing group. Examples of such a substituent include an iodine atom, a hydroxy group, a carboxy group, a cyano group, a nitro group, an alkyl group, an alkoxy group, an alkoxycarbonyl group, an alkoxycarbonyloxy group, an acyl group, an acyloxy group, and the like.

Examples of a cation species in the cation (P) include a sulfonium cation (S⁺), an iodonium cation (I⁺), and the like. Of these, the sulfonium cation is preferred.

The cation (P) includes at least one aromatic ring (p). The cation (P) may include an aromatic ring structure other than the aromatic ring (p). In the case in which the cation species of the cation (P) is a sulfonium cation, the cation (P) is classified broadly into: a form (form 1) which includes three aromatic rings; and a form (form 2) which includes one aromatic ring and one ring structure which contains a sulfur atom of a sulfonium cation as a ring-constituting atom. In the case of form 1, the cation (P) preferably includes at least two aromatic rings (p). Examples of the ring structure containing the sulfur atom of the sulfonium cation as the ring-constituting atom include a benzothiophene ring, a dibenzothiophene ring, and the like.

The cation (P) is preferably a cation (hereinafter, may be also referred to as “cation (P-1) or (P-2)”) represented by the following formula (2-1) or (2-2).

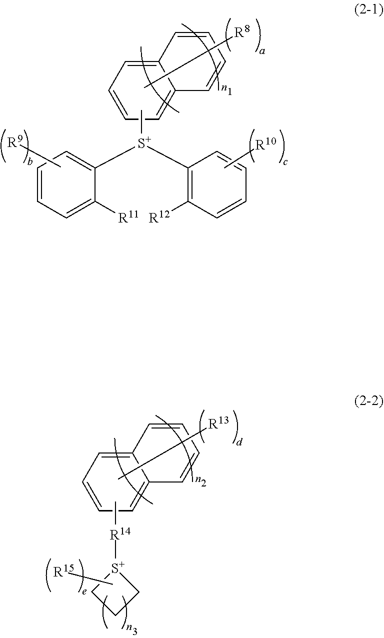

In the formula (2-1), a is an integer of 0 to 7, b is an integer of 0 to 4, and c is an integer of 0 to 4, wherein a sum of a, b, and c is no less than 1; R¹, R⁹, and R¹⁰ each independently represent a halogen atom, a hydroxy group, a nitro group, or a monovalent organic group having 1 to 20 carbon atoms, wherein at least one of R¹, R⁹, and R¹⁰ represents a fluorine atom or a monovalent fluorinated hydrocarbon group having 1 to 10 carbon atoms, in a case in which a is no less than 2, a plurality of R⁸s are identical or different from each other, in a case in which b is no less than 2, a plurality of R⁹s are identical or different from each other, and in a case in which c is no less than 2, a plurality of R¹⁰s are identical or different from each other; n1 is 0 or 1; R¹¹ and R¹² each independently represent a hydrogen atom, a fluorine atom, or a monovalent fluorinated hydrocarbon group having 1 to 10 carbon atoms, or R¹¹ and R¹² taken together represent a single bond; and n1 is 0 or 1.

In the above formula (2-2), d is an integer of 1 to 7; e is an integer of 0 to 10; in a case in which d is 1, R¹³ represents a fluorine atom or a monovalent fluorinated hydrocarbon group having 1 to 10 carbon atoms, and in a case in which d is no less than 2, a plurality of R⁶s are identical or different from each other, and each R¹³ represents a halogen atom, a hydroxy group, a nitro group, or a monovalent organic group having 1 to 20 carbon atoms, wherein at least one of the plurality of R¹³s represents a fluorine atom or a monovalent fluorinated hydrocarbon group having 1 to 10 carbon atoms; R¹⁴ represents a single bond or a divalent organic group having 1 to 20 carbon atoms; R¹⁵ represents a halogen atom, a hydroxy group, a nitro group, or a monovalent organic group having 1 to 20 carbon atoms, wherein in a case in which e is no less than 2, a plurality of R¹⁵s are identical or different from each other; n₂ is 0 or 1; and n₃ is an integer of 0 to 3.

The monovalent fluorinated hydrocarbon group having 1 to 10 carbon atoms is a group obtained by substituting a part or all of hydrogen atoms in a monovalent hydrocarbon group having 1 to 10 carbon atoms with a fluorine atom. Specific examples include fluorinated alkyl groups, e.g., partially fluorinated alkyl groups such as a fluoromethyl group, a difluoromethyl group, a difluoroethyl group, a trifluoroethyl group, and a trifluoropropyl group; perfluoroalkyl groups such as a trifluoromethyl group, a pentafluoroethyl group, and a hexafluoropropyl group; and the like. Of these, the perfluoroalkyl groups are preferred, and a trifluoromethyl group is more preferred.

Examples of the divalent organic group having 1 to 20 carbon atoms include a group obtained by removing one hydrogen atom from the monovalent organic group having 1 to 20 carbon atoms, and the like.

A sum of a, b, and c is preferably 1 to 6, and more preferably 1 to 5. a, b, and c may be appropriately selected from within this range.

It is preferred that R¹¹ and R¹² each represent a hydrogen atom, or that R¹¹ and R¹² taken together represent a single bond.

The cation (P) is preferably the cation (P-1).

Examples of the cation (P-1) include cations (hereinafter, may be also referred to as cations (P-1-1) to (P-1-7) represented by the following formulae (2-1-1) to (2-1-7), and the like.

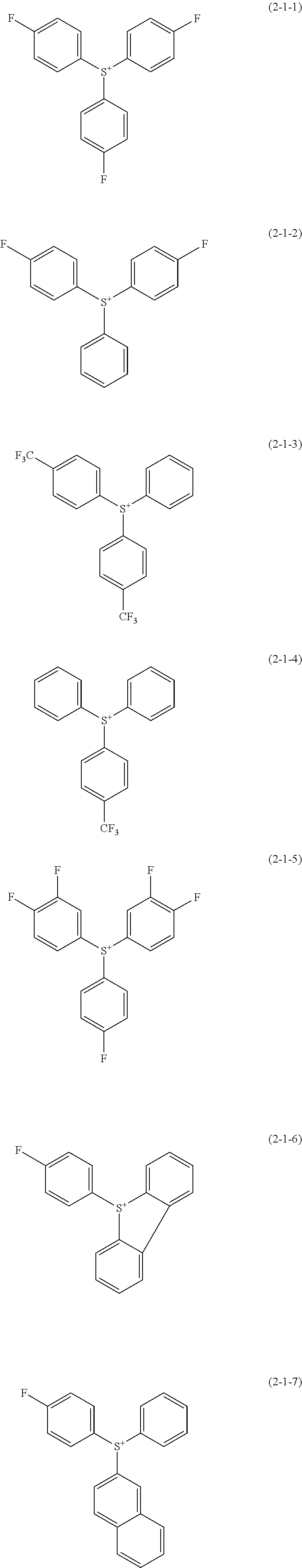

### Anion (Q)

The anion (Q) is a monovalent organic acid anion. The anion (Q) includes a monovalent anion group. Examples of the monovalent anion group include a sulfonate anion group (—SO3⁻), a carboxylate anion group (—COO⁻), an imidic acid anion (—C(═NR)—O⁻), and the like. Of these, the sulfonate anion group or the carboxylate anion group is preferred.

Hereinafter, among the anions (Q), one having a sulfonate anion group as the monovalent anion group is referred to as “anion (Q-1)”, and one having a carboxylate acid anion group as the monovalent anion group is referred to as “anion (Q-2)”.

### Anion (Q-1)

In the case in which the compound (Z) has the anion (Q-1), the compound (Z) functions as the radiation-sensitive acid generating agent. In this case, the radiation-sensitive resin composition preferably contains an acid diffusion control agent. Examples of the acid diffusion control agent include the compound (Z) in the case of functioning as the acid diffusion control agent, the acid diffusion control agent (C), described later, and the like. Of these, the acid diffusion control agent is preferably the compound (Z) in the case of functioning as the acid diffusion control agent. In other words, the radiation-sensitive resin composition preferably contains the compound (Z) having the anion (Q-1), and the compound (Z) having the anion (Q-2). In this case, the CDU performance resulting from the radiation-sensitive resin composition can be further improved.

The anion (Q-1) is not particularly limited as long as it is used as an anion in an onium salt-type radiation-sensitive acid generating agent, and examples thereof include an sulfonate anion represented by the following formula (4-1).

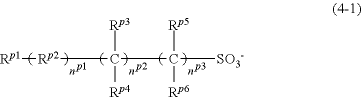

In the above formula (4-1), R^{p1} represents a monovalent group containing a ring structure having 5 or more ring atoms; R^{p2} represents a divalent linking group; R^{p3} and R^{p4} each independently represent a hydrogen atom, a fluorine atom, a monovalent hydrocarbon group having 1 to 20 carbon atoms, or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10, n^{p2} is an integer of 0 to 10, and n^{p3} is an integer of 0 to 10, wherein a sum of n^{p1}, n^{p2}, and n^{p3} is no less than 1 and no greater than 30, in a case in which n^{p1} is no less than 2, a plurality of R^{p2}s are identical to or different from each other, in a case in which n^{p2} is no less than 2, a plurality of R^{p3}s are identical to or different from each other and a plurality of R^{p4}s are identical to or different from each other, and in a case in which n^{p3} is no less than 2, a plurality of R^{p5}s are identical to or different from each other and a plurality of R^{p6}s are identical to or different from each other.

The ring structure having 5 or more ring atoms is exemplified by an aliphatic hydrocarbon ring having 5 or more ring atoms, an aliphatic heterocycle having 5 or more ring atoms, an aromatic hydrocarbon ring having 6 or more ring atoms, an aromatic heterocyclic structure having 5 or more ring atoms, or a combination thereof.

Examples of the aliphatic hydrocarbon ring structure having 5 or more ring atoms include: monocyclic saturated aliphatic rings such as a cyclopentane ring, a cyclohexane ring, a cycloheptane ring, a cyclooctane ring, a cyclononane ring, a cyclodecane ring and a cyclododecane ring; monocyclic unsaturated aliphatic rings such as a cyclopentene ring, a cyclohexene ring, a cycloheptene ring, a cyclooctene ring and a cyclodecene ring; polycyclic saturated aliphatic rings such as a norbornane ring, an adamantane ring, a tricyclodecane ring and a tetracyclododecane ring, and a steroid ring; polycyclic unsaturated aliphatic rings such as a norbornene ring and a tricyclodecene ring; and the like. The “steroid ring” as referred to means a structure having, as a basic skeleton, a skeleton (sterane skeleton) in which three 6-membered rings and one 4-membered ring are fused.

Examples of the aliphatic heterocycle having 5 or more ring atoms include: lactone rings such as a hexanolactone ring and a norbornanelactone ring; sultone rings such as a hexanosultone ring and a norbornanesultone ring; oxygen atom-containing heterocycles such as a dioxolane ring, an oxacycloheptane ring, and an oxanorbornane ring; nitrogen atom-containing heterocycles such as an azacyclohexane ring and a diazabicyclooctane ring; sulfur atom-containing heterocycles such as a thiacyclohexane ring and a thianorbornane ring; and the like.

Examples of the aromatic hydrocarbon ring having 6 or more ring atoms include: a benzene ring; fused polycyclic aromatic hydrocarbon rings such a naphthalene ring, an anthracene ring, a fluorene ring, a biphenylene ring, a phenanthrene ring, and a pyrene ring; ring-assembled aromatic hydrocarbon rings such as a biphenyl ring, a terphenyl ring, a binaphthalene ring, and a phenylnaphthalene ring; a 9,10-ethanoanthracene ring; and the like.

Examples of the aromatic heterocycle having 5 or more ring atoms include: oxygen atom-containing heterocycles such as a furan ring, a pyran ring, a benzofuran ring, and a benzopyran ring; nitrogen atom-containing heterocycles such as a pyridine ring, a pyrimidine ring, and an indole ring; sulfur atom-containing heterocycles such as a thiophene ring; and the like.

The ring structures may be such that a part or all of hydrogen atoms bonded to atoms constituting the ring structures are substituted with a substituent. Examples of the substituent include: halogen atoms such as a fluorine atom and an iodine atom; a hydroxy group; a carboxy group; a cyano group; a nitro group; an alkyl group; an alkoxy group; an alkoxycarbonyl group; an alkoxycarbonyloxy group; an acyl group; an acyloxy group; an oxo group (═O); and the like.

The lower limit of the number of ring atoms of the ring structure is preferably 6, more preferably 8, still more preferably 9, and particularly preferably 10. The upper limit of the number of ring atoms is preferably 25.

R^{p1} represents preferably a monovalent group including the aliphatic hydrocarbon ring having 5 or more ring atoms, a monovalent group including the aliphatic heterocycle having 5 or more ring atoms, or the aromatic hydrocarbon ring having 6 or more ring atoms.

Examples of the divalent linking group which may be represented by R^{p2} include a carbonyl group, an ether group, a carbonyloxy group, a sulfide group, a thiocarbonyl group, a sulfonyl group, a divalent hydrocarbon group, a combination thereof, and the like.

The monovalent hydrocarbon group having 1 to 20 carbon atoms which may be represented by each of R^{p3} and R^{p4} is exemplified by an alkyl group having 1 to 20 carbon atoms, and the like. The monovalent fluorinated hydrocarbon group having 1 to 20 carbon atoms which may be represented by each of R^{p3} and R^{p4} is exemplified by a fluorinated alkyl group having 1 to 20 carbon atoms, and the like. R^{p3} and R^{p4} each represent preferably a hydrogen atom, a fluorine atom, or a fluorinated alkyl group, more preferably a hydrogen atom, a fluorine atom, or a perfluoroalkyl group, and still more preferably a hydrogen atom, a fluorine atom, or a trifluoromethyl group.

The monovalent fluorinated hydrocarbon group having 1 to 20 carbon atoms which may be represented by each of R^{p5} and R^{p6} is exemplified by a fluorinated alkyl group having 1 to 20 carbon atoms, and the like. R^{p5} and R^{p6} each independently represent preferably a fluorine atom or a fluorinated alkyl group, more preferably a fluorine atom or a perfluoroalkyl group, still more preferably a fluorine atom or a trifluoromethyl group, and particularly preferably a fluorine atom.

n^{p1} is preferably 0 to 5, more preferably 0 to 2, and still more preferably 0 or 1.

n^{p2} is preferably 0 to 5, more preferably 0 to 2, and still more preferably 0 or 1.

The lower limit of n^{p3} is preferably 1, and more preferably 2. When n^{p3} is no less than 1, strength of the acid can be enhanced. The upper limit of n^{p3} is preferably 4, more preferably 3, and still more preferably 2.

The lower limit of the sum of n^{p1}, n^{p2}, and n^{p3} is preferably 2, and more preferably 4. The upper limit of the sum of n^{p1}, n^{p2}, and n^{p3} is preferably 20, and more preferably 10.

The anion (Q-1) is preferably a sulfonate anion represented by the following formulae (4-1-1) to (4-1-7).

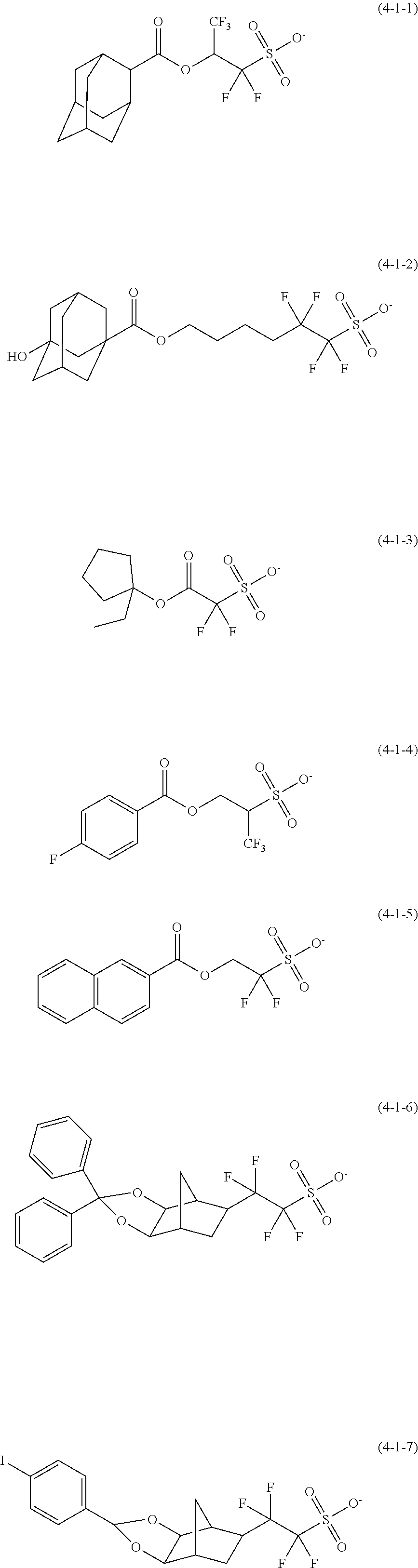

The compound (Z) which may be used as the radiation-sensitive acid generating agent is a compound obtained by appropriately combining the cation (P) and the anion (Q-1).

### Anion (Q-2)

In the case in which the compound (Z) has the anion (Q-2), the compound (Z) functions as the acid diffusion control agent. In this case, the radiation-sensitive resin composition preferably has a radiation-sensitive acid generating agent. Examples of the radiation-sensitive acid generating agent include the compound (Z) in the case of functioning as the radiation-sensitive acid generating agent, the acid-generating agent (B), described later, and the like. Of these, the radiation-sensitive acid generating agent is preferably the compound (Z) in the case of functioning as the radiation-sensitive acid generating agent.

The anion (Q-2) is not particularly limited as long as it is used as an anion in a photodegradable base that is photosensitized by exposure to generate a weak acid, and examples thereof include a substituted or unsubstituted salicylate anion, a group obtained by replacing the sulfonate anion group in the above formula (4-1) with a carboxylate anion group, and the like.

Preferred examples of the anion (Q-2) include sulfonate anions represented by the following formulae (4-2-1) to (4-2-6).

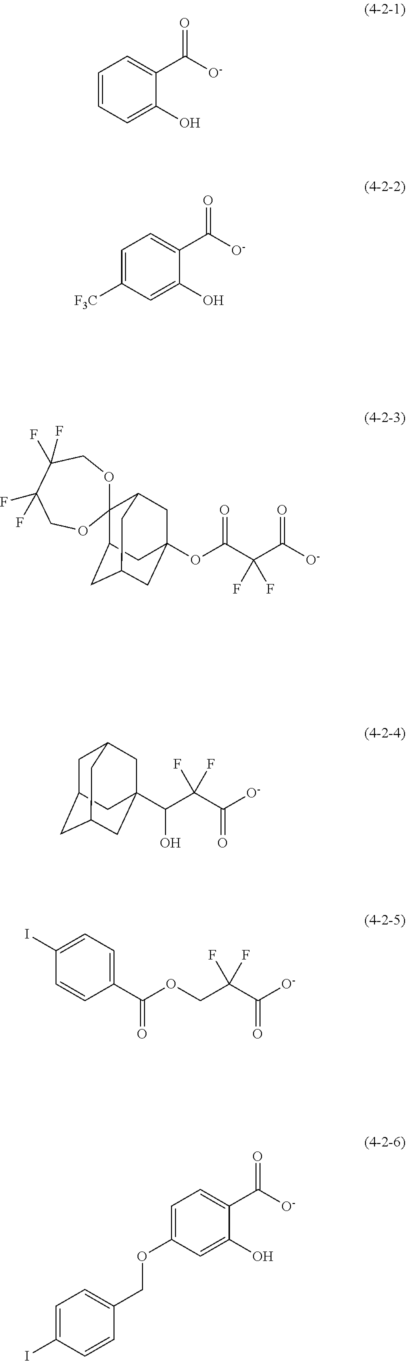 [SMILES: O=C([O-])c1ccccc1O ; O=C([O-])c1ccc(C(F)(F)F)cc1O ; O=C([O-])C(F)(F)C(=O)OC12CC3CC(C1)C1(OCC(F)(F)C(F)(F)CO1)C(C3)C2 ; O=C([O-])C(F)(F)C(O)C12CC3CC(CC(C3)C1)C2 ; O=C(OCC(F)(F)C(=O)[O-])c1ccc(I)cc1 ; O=C([O-])c1ccc(OCc2ccc(I)cc2)cc1O]

The compound (Z) which may be used as the acid diffusion control agent is a compound obtained by appropriately combining the cation (P) and the anion (Q-2).

### (B) Acid Generating Agent

The acid generating agent (B) is a radiation-sensitive acid generating agent other than the compound (Z) as the radiation-sensitive acid generating agent. The acid generating agent (B) is exemplified by an onium salt compound, an N-sulfonyloxyimide compound, a sulfonimide compound, a halogen-containing compound, a diazoketone compound, and the like.

Examples of the acid generating agent (B) include a compound obtained by combining a triphenylsulfonium cation and the anion (Q-1) described in the above section “(Z) Compound”, and the like.

In the case in which the radiation-sensitive resin composition contains the acid generating agent (B), the lower limit of a content of the acid generating agent (B) in the radiation-sensitive resin composition with respect to 100 parts by mass of the polymer (A) is preferably 1 part by mass, more preferably 5 parts by mass, and still more preferably 10 parts by mass. The upper limit of the content is preferably 50 parts by mass, more preferably 40 parts by mass, and still more preferably 30 parts by mass.

### (C) Acid Diffusion Control Agent

The acid diffusion control agent (C) is an acid diffusion control agent other than the compound (Z) as the acid diffusion control agent. The acid diffusion control agent (C) is exemplified by a nitrogen atom-containing compound, a photodegradable base that is photosensitized by an exposure to generate a weak acid, and the like.

Examples of the nitrogen atom-containing compound include: amine compounds such as tripentylamine and trioctylamine; amide group-containing compounds such as formamide and N,N-dimethylacetamide; urea compounds such as urea and 1,1-dimethylurea; nitrogen-containing heterocyclic compounds such as pyridine, N-(undecylcarbonyloxyethyl) morpholine, and N-t-pentyloxycarbonyl-4-hydroxypiperidine; and the like.

Examples of the photodegradable base include a compound containing an onium cation degraded by exposure, and an anion of a weak acid; and the like. In a light-exposed region, the photodegradable base generates a weak acid from: a proton produced upon degradation of the onium cation; and the anion of the weak acid. Consequently, acid diffusion controllability decreases.

Examples of the acid diffusion control agent (C) include a compound obtained by combining a triphenylsulfonium cation and the anion (Q-2) described in the above section “(Z) Compound”, and the like.

In the case in which the radiation-sensitive resin composition contains the acid diffusion control agent (C), the lower limit of a proportion of the acid diffusion control agent (C) in the radiation-sensitive resin composition acid with respect to 100 mol % of the radiation-sensitive acid generating agent (the compound (Z) functioning as the radiation-sensitive acid generating agent and/or the acid generating agent (B)) contained in the radiation-sensitive resin composition is preferably 10 mol %, more preferably 20 mol %, and still more preferably 30 mol %. The upper limit of the proportion is preferably 90 mol %, more preferably 80 mol %, and still more preferably 70 mol %.

### (D) Organic Solvent

The radiation-sensitive resin composition typically contains the organic solvent (D). The organic solvent (D) is not particularly limited as long as it is a solvent capable of dissolving or dispersing at least the polymer (A) and the compound (Z), as well as the acid generating agent (B), the acid diffusion control agent (C), the polymer (F), and the other optional component(s) which is/are contained as needed.

The organic solvent (D) is exemplified by an alcohol solvent, an ether solvent, a ketone solvent, an amide solvent, an ester solvent, a hydrocarbon solvent, and the like. The radiation-sensitive resin composition may contain one, or two or more types of the organic solvent (D).

### Examples of the Alcohol Solvent Include:

aliphatic monohydric alcohol solvents having 1 to 18 carbon atoms such as 4-methyl-2-pentanol, n-hexanol, and diacetone alcohol;
alicyclic monohydric alcohol solvents having 3 to 18 carbon atoms such as cyclohexanol;
polyhydric alcohol solvents having 2 to 18 carbon atoms such as 1,2-propylene glycol;
polyhydric alcohol partial ether solvents having 3 to 19 carbon atoms such as propylene glycol monomethyl ether; and the like.

### Examples of the Ether Solvent Include:

dialkyl ether solvents such as diethyl ether, dipropyl ether, dibutyl ether, dipentyl ether, diisoamyl ether, dihexyl ether, and diheptyl ether;
cyclic ether solvents such as tetrahydrofuran and tetrahydropyran;
aromatic ring-containing ether solvents such as diphenyl ether and anisole; and the like.

### Examples of the Ketone Solvent Include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethylnonanone;
cyclic ketone solvents such as cyclopentanone, cyclohexanone, cycloheptanone, cyclooctanone, and methylcyclohexanone;
2,4-pentanedione, acetonylacetone, and acetophenone; and the like.

### Examples of the Amide Solvent Include:

cyclic amide solvents such as N,N′-dimethylimidazolidinone and N-methylpyrrolidone;
chain amide solvents such as N-methylformamide, N,N-dimethylformamide, N,N-diethylformamide, acetamide, N-methylacetamide, N,N-dimethylacetamide, and N-methylpropionamide; and the like.

### Examples of the Ester Solvent Include:

monocarboxylic acid ester solvents such as n-butyl acetate and ethyl lactate;
lactone solvents such as γ-butyrolactone and valerolactone;
polyhydric alcohol carboxylate solvents such as propylene glycol acetate; polyhydric alcohol partial ether carboxylate solvents such as propylene glycol monomethyl ether acetate;
polyhydric carboxylic acid diester solvents such as diethyl oxalate;
carbonate solvents such as dimethyl carbonate and diethyl carbonate; and the like.

### Examples of the Hydrocarbon Solvent Include:

aliphatic hydrocarbon solvents having 5 to 12 carbon atoms such as n-pentane and n-hexane;
aromatic hydrocarbon solvents having 6 to 16 carbon atoms such as toluene and xylene; and the like.

The organic solvent (D) is preferably the alcohol solvent, the ester solvent or a combination of the same, more preferably the polyhydric alcohol partial ether solvent having 3 to 19 carbon atoms, the polyhydric alcohol partial ether carboxylate solvent, or a combination of the same, and still more preferably propylene glycol monomethyl ether propylene glycol monomethyl ether acetate, or a combination of the same.

In the case of the radiation-sensitive resin composition containing the organic solvent (D), the lower limit of a proportion of the organic solvent (D) with respect to total components contained in the radiation-sensitive resin composition is preferably 50% by mass, more preferably 60% by mass, still more preferably 70% by mass, and particularly preferably 80% by mass. The upper limit of the proportion is preferably 99.9% by mass, more preferably 99.5% by mass, and still more preferably 99.0% by mass.

### (F) Polymer

The polymer (F) is a polymer that differs from the polymer (A), and has a percentage content of fluorine atoms which is greater than that of the polymer (A). In general, a more hydrophobic polymer than a polymer that serves as a base polymer tends to be localized in a resist film surface layer. Since the polymer (F) has a percentage content of fluorine atoms which is greater than that of the polymer (A), due to characteristics resulting from the hydrophobicity, the polymer (F) tends to be localized in the resist film surface layer. As a result, in the case in which the radiation-sensitive resin composition contains the polymer (F), a cross-sectional shape of a resist pattern to be formed is expected to be favorable. In the case in which the radiation-sensitive resin composition contains the polymer (F), rectangularity of the cross-sectional shape of the resist pattern can be further improved.

The radiation-sensitive resin composition may contain the polymer (F) as, for example, a surface conditioning agent of a resist film. The radiation-sensitive resin composition may contain one type, or two or more types of the polymer (F).

The lower limit of a percentage content of fluorine atoms in the polymer (F) is preferably 1% by mass, more preferably 2% by mass, and still more preferably 3% by mass. The upper limit of the percentage content of fluorine atoms is preferably 60% by mass, more preferably 50% by mass, and still more preferably 40% by mass. It is to be noted that the percentage content by mass of fluorine atoms in the polymer may be calculated based on the structure of the polymer determined by ¹³C-NMR spectroscopy.

The mode of incorporation of the fluorine atom in the polymer (F) is not particularly limited, and the fluorine atom may be bonded to either the main chain or the side chain of the polymer (F). In a preferred mode of incorporation of the fluorine atom in the polymer (F), the polymer (F) has a structural unit (hereinafter, may be also referred to as “structural unit (f)”) including a fluorine atom. The polymer (F) may further have a structural unit aside from the structural unit (F). The polymer (F) may have one, or two or more types of each structural unit.

The lower limit of the Mw of the polymer (F) as determined by GPC is preferably 2,000, more preferably 3,000, and still more preferably 5,000. The upper limit of the Mw is preferably 50,000, more preferably 20,000, and still more preferably 10,000.

The upper limit of a ratio (Mw/Mn) of the Mw to the Mn of the polymer (F) as determined by GPC is preferably 5.0, more preferably 3.0, still more preferably 2.5, and particularly preferably 2.0. The lower limit of the ratio is typically 1.0, and preferably 1.2.

In the case in which the radiation-sensitive resin composition contains the polymer (F), the lower limit of a content of the polymer (F) with respect to 100 parts by mass of the polymer (A) is preferably 0.5 parts by mass, and more preferably 1 part by mass. The upper limit of the content is preferably 20 parts by mass, and more preferably 10 parts by mass.

Similarly to the polymer (A), the polymer (F) can be synthesized by, for example, polymerizing a monomer that gives each structural unit according to a well-known procedure.

Each structural unit contained in the polymer (F) is described below.

### Structural Unit (f)

The structural unit (f) is a structural that includes a fluorine atom. The percentage content of fluorine atoms in the polymer (F) can be adjusted by adjusting the proportion of the structural unit (f) in the polymer (F). Examples of the structural unit (f) include a structural unit (hereinafter, may be also referred to as “structural unit (f-1)”) represented by the following formula (f), and the like.

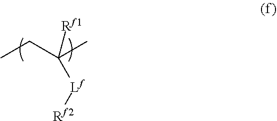

In the above formula (f), R^{f1} represents a hydrogen atom, a fluorine atom, a methyl group, or a trifluoromethyl group; L^{f} represents a single bond, an oxygen atom, a sulfur atom, —COO—, —SO₂NH—, —CONH—, or —OCONH—; and R^{f2} represents a substituted or unsubstituted monovalent fluorinated hydrocarbon group having 1 to 20 carbon atoms.

In light of copolymerizability of a monomer that gives the structural unit (f-1), R^{f1} represents preferably a hydrogen atom or a methyl group, and more preferably a methyl group.

L^{f} represents preferably —COO—.

The substituted or unsubstituted monovalent fluorinated hydrocarbon group having 1 to 20 carbon atoms represented by R^{f2} is exemplified by a fluorinated alkyl group, and the like.

A part or all of hydrogen atoms in the fluorinated hydrocarbon group may be substituted with a substituent. Examples of the substituent include groups similar to those exemplified as the substituent which may be contained in, e.g., R² in the above-described formula (1), and the like.

In the case in which the polymer (F) has the structural unit (f), the lower limit of a proportion of the structural unit (f) contained with respect to total structural units constituting the polymer (F) is preferably 10 mol %, more preferably 20 mol %, and still more preferably 30 mol %. The upper limit of the proportion is, for example, 100 mol %.

### Other Structural Unit(s)

Examples of the other structural unit(s) include a structural unit having an acid-labile group, and the like. Examples of the structural unit having an acid-labile group include the structural unit (III) described in the above-describe section “(A) Polymer”, and the like.

### Other Optional Component(s)

The other optional component(s) is/are exemplified by a surfactant and the like. The radiation-sensitive resin composition may contain one, or two or more types each of the other optional component(s).

### Method of Forming Resist Pattern

The method of forming a resist pattern according to the other embodiment of the present disclosure includes: a step (hereinafter, may be also referred to as “applying step”) of applying a radiation-sensitive resin composition directly or indirectly on a substrate; a step (hereinafter, may be also referred to as “exposing step”) of exposing a resist film formed by the applying step; and a step (hereinafter, may be also referred to as “developing step”) of developing the resist film exposed.

In the applying step, the radiation-sensitive resin composition of the one embodiment of the present disclosure is used as the radiation-sensitive resin composition. Thus, the method of forming a resist pattern of the other embodiment of the present disclosure enables forming a resist pattern being superior in CDU performance and the ability to inhibit development defects, with high sensitivity.

Each step included in the method of forming a resist pattern is described below.

### Applying Step

In this step, the radiation-sensitive resin composition is applied directly or indirectly on the substrate. By this step, the resist film is formed directly or indirectly on the substrate.

In this step, the radiation-sensitive resin composition of the one embodiment of the present disclosure, described above, is used as the radiation-sensitive resin composition.

The substrate is exemplified by a conventionally well-known substrate such as a silicon wafer, a wafer coated with silicon dioxide or aluminum, and the like.

An application procedure is exemplified by spin coating, cast coating, roll coating, and the like. After the application, prebaking (hereinafter, may be also referred to as “PB”) may be carried out as needed for evaporating the solvent remaining in the coating film. The lower limit of a PB temperature is preferably 60° C., and more preferably 80° C. The upper limit of the PB temperature is preferably 150° C., and more preferably 140° C. The lower limit of a PB time period is preferably 5 sec, and more preferably 10 sec. The upper limit of the PB time period is preferably 600 sec, and more preferably 300 sec. The lower limit of an average thickness of the resist film formed is preferably 10 nm, and more preferably 20 nm. The upper limit of the average thickness is preferably 1,000 nm, and more preferably 500 nm.

### Exposing Step

In this step, the resist film formed by the applying step is exposed. This exposure is carried out by irradiation with an exposure light through a photomask (as the case may be, through a liquid immersion medium such as water). As the exposure light, far ultraviolet rays, EUV, or electron beams are preferred; an ArF excimer laser beam (wavelength: 193 nm), a KrF excimer laser beam (wavelength: 248 nm), EUV (wavelength: 13.5 nm), or electron beams are more preferred; a KrF excimer laser beam, EUV, or electron beams are still more preferred; and EUV or electron beams are particularly preferred.

It is preferred that post exposure baking (hereinafter, may be also referred to as “PEB”) is carried out after the exposure. This PEB enables an increase in a difference in solubility of the resist film in a developer solution between the light-exposed regions and light-unexposed regions. The lower limit of a temperature of the PEB is preferably 50° C., and more preferably 80° C. The upper limit of the temperature of the PEB is preferably 180° C., and more preferably 130° C. The lower limit of a time period of the PEB is preferably 5 sec, more preferably 10 sec, and still more preferably 30 sec. The upper limit of the time period of the PEB is preferably 600 sec, more preferably 300 sec, and still more preferably 100 sec.

### Developing Step

In this step, the resist film exposed is developed. Accordingly, formation of a predetermined resist pattern is enabled. The development procedure in the developing step may be carried out by either development with an alkali, or development with an organic solvent.

In the case of the development with an alkali, the developer solution for use in the development is exemplified by alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (hereinafter, may be also referred to as “TMAH”), pyrrole, piperidine, choline, 1,8-diazabicyclo-[5.4.0]-7-undecene, and 1,5-diazabicyclo-[4.3.0]-5-nonene; and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent, and an alcohol solvent; a solution containing the organic solvent; and the like. Exemplary organic solvents include the solvents exemplified as the organic solvent (D) for the radiation-sensitive resin composition, and the like.

### EXAMPLES

Hereinafter, the present invention is explained in detail by way of Examples, but the present invention is not in any way limited to these Examples. Measuring methods for various types of physical property values are shown below.

### Weight Average Molecular Weight (Mw), Number Average Molecular Weight (Mn), and Polydispersity Index (Mw/Mn)

Measurements of the Mw and the Mn of the polymer were carried out in accordance with the conditions described in the aforementioned paragraph “Method for Measuring Mw and Mn”. The polydispersity index (Mw/Mn) of the polymer was calculated from the measurement results of the Mw and the Mn.

### Synthesis of Monomer (X)

Compounds (hereinafter, may be also referred to as “monomers (X-1) to (X-9)”) represented by the following formulae (X-1) to (X-9) as the monomer (X) were synthesized in accordance with the following method.

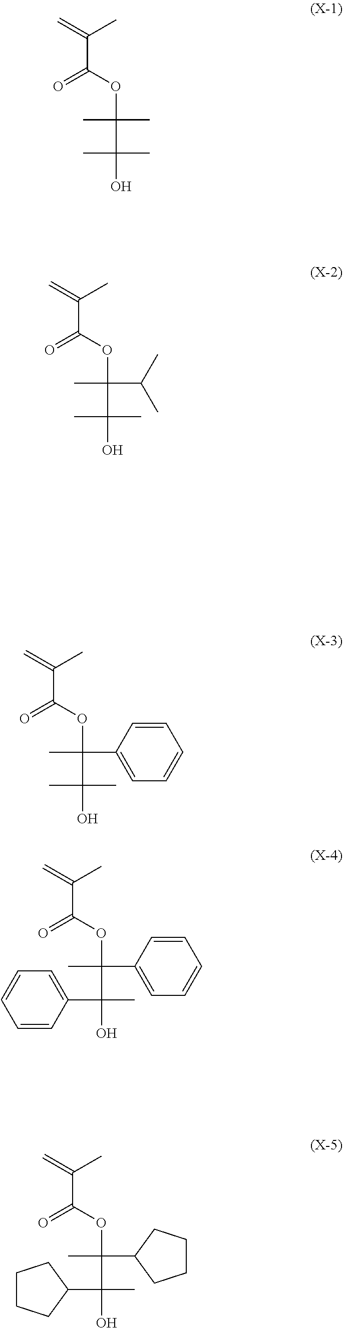 [SMILES: C=C(C)C(=O)OC(C)(C)C(C)(C)O ; C=C(C)C(=O)OC(C)(C(C)C)C(C)(C)O ; C=C(C)C(=O)OC(C)(c1ccccc1)C(C)(C)O ; C=C(C)C(=O)OC(C)(c1ccccc1)C(C)(O)c1ccccc1 ; C=C(C)C(=O)OC(C)(C1CCCC1)C(C)(O)C1CCCC1]

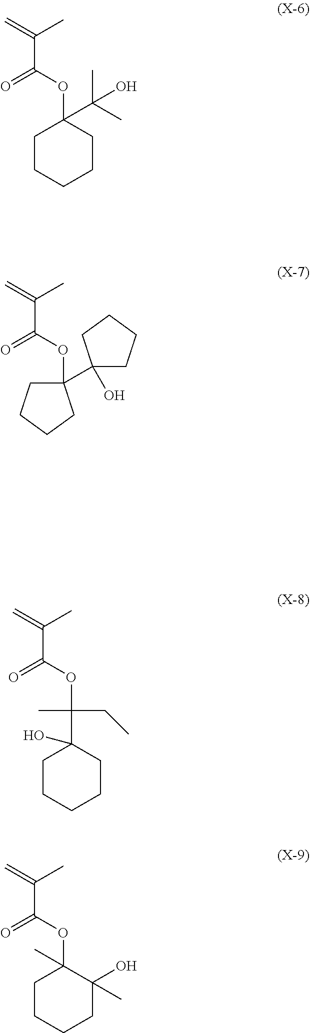

### Synthesis Example 1-1: Synthesis of Monomer (X-1)

Into a reaction vessel were charged 200 mmol of 2,3-dimethylbutane-2,3-diol, 300 mmol of triethylamine, 100 mmol of 1,4-diazabicyclo[2.2.2]octane, and 150 g of tetrahydrofuran, and mixing was performed at 0° C. for 1 hour. Thereafter, 300 mmol of methacryloyl chloride was slowly added dropwise, and stirring was performed at 60° C. for 2 hrs. A thus resulting reaction liquid was cooled to no greater than 30° C., and an aqueous solution of saturated ammonium chloride was added to terminate the reaction. Extraction was performed using ethyl acetate. An organic layer thus obtained was washed with water, and dried with sodium sulfate. Thereafter, a solvent was distilled, and purified by column chromatography. A monomer (X-1) was thus obtained with a favorable yield.

A synthesis scheme of the monomer (X-1) is shown below. In the following synthesis scheme, NEt₃ represents triethylamine, and DABCO represents 1,4-diazabicyclo[2.2.2]octane.

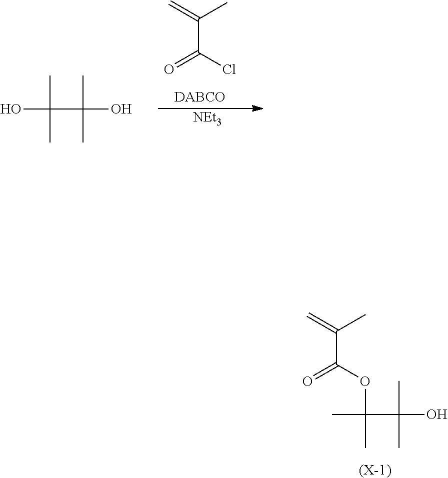

### Synthesis Examples 1-2 to 1-9: Syntheses of Monomers (X-2) to (X-9)

Monomers (X-2) to (X-9) were synthesized similarly to Synthesis Example 1-1, except for appropriately selecting each precursor.

### Synthesis of Polymer (A)

Each of monomers (A-1) to (A-24), (CA-1) to (CA-2) as the polymer (A) was synthesized in accordance with the following method. For syntheses of the polymers (A), the monomers (X-1) to (X-9), and compounds (hereinafter, may be also referred to as “monomers (M-1) to (M-16)”) represented by the following formulae (M-1) to (M-16) were used. In the following Synthesis Examples, unless otherwise specified particularly, the term “parts by mass” means a value, provided that the total mass of the monomers used was 100 parts by mass, and the term “mol %” means a value, provided that the total mol number of the monomers used was 100 mol %.

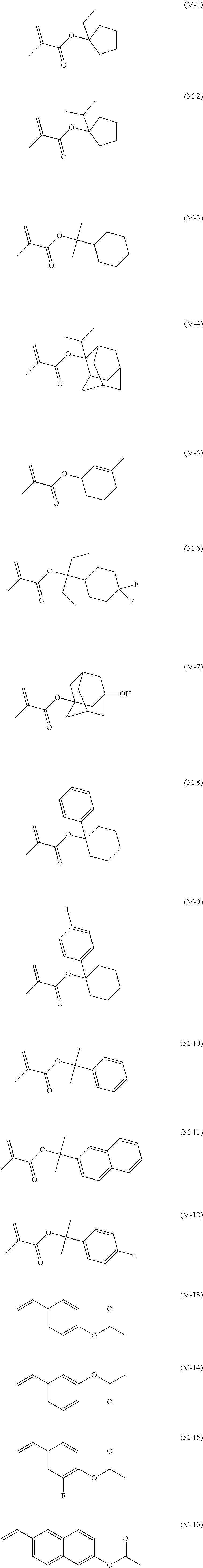

### Synthesis Example 2-1: Synthesis of Polymer (A-1)

The monomer (X-1), the monomer (M-1), and the compound (X-13) were dissolved in propylene glycol monomethyl ether (200 parts by mass with respect to the total monomers) such that the molar ratio become 10/45/45. A monomer solution was prepared by adding azobisisobutyronitrile (hereinafter, may be also referred to as “AIBN”) as an initiator at a content of 5 mol % with respect to the total monomers. Meanwhile, propylene glycol monomethyl ether (100 parts by mass with respect to the total monomers) was charged into an empty vessel and heated to 85° C. with stirring. Next, the monomer solution prepared as described above was added dropwise over 3 hrs, and a thus resulting solution was further heated for 3 hrs at 85° C., for a total polymerization reaction time of 6 hrs. After completion of the polymerization reaction, the polymerization liquid was cooled to room temperature. The cooled polymerization solution was charged into hexane (500 parts by mass with respect to the polymerization solution), and a thus precipitated white powder was filtered off. The white powder obtained by filtration was washed twice with 100 parts by mass of hexane with respect to the polymerization solution. Subsequently, the white powder was filtered off and dissolved in propylene glycol monomethyl ether (300 parts by mass). Next, methanol (500 parts by mass), triethylamine (50 parts by mass), and ultra-pure water (10 parts by mass) were added to a resulting solution, and a hydrolysis reaction was performed at 70° C. for 6 hrs with stirring. After completion of the reaction, the remaining solvent was distilled away and a solid thus obtained was dissolved in acetone (100 parts by mass). The solution was added dropwise to 500 parts by mass of water to permit coagulation of the resin, a solid thus obtained was filtered off, and drying at 50° C. for 12 hrs gave a white powdery polymer (A-1). The Mw of the polymer (A-1) was 6,700, and the Mw/Mn was 1.5.

### Synthesis Examples 2-2 to 2-26: Synthesis of Polymers (A-2) to (A-24) and (CA-1) to (CA-2)

Polymers (A-2) to (A-24), and (CA-1) to (CA-2) were synthesized similarly to Synthesis Example 2-1, except that each monomer of the type and in a blend proportion as shown in Table 1 below was used.

Types and usage proportions of the monomers that give each structural unit in the polymers obtained in Synthesis Examples 2-1 to 2-30, as well as the Mw and the Mw/Mn thereof are shown in Table 1 below. In Table 1 below, “-” indicates that the corresponding monomer was not used.

TABLE 1

| | | Monomer that | | Monomer that | | Monomer that | | Monomer that | | | |
|---|---|---|---|---|---|---|---|---|---|---|---|
| | | gives structural | | gives structural | | gives structural | | gives other | | | |
| | | unit (I) | | unit (II) | | unit (III) | | structural unit | | | |
| | | | blending | | blending | | blending | | blending | | |
| | (A) | | amount | | amount | | amount | | amount | | |
| | Polymer | type | (mol %) | type | (mol %) | type | (mol %) | type | (mol %) | Mw | Mw/Mn |
| Synthesis | A-1 | X-1 | 10 | M-13 | 45 | M-1 | 45 | — | — | 6,700 | 1.5 |
| Example 2-1 | | | | | | | | | | | |
| Synthesis | A-2 | X-2 | 10 | M-13 | 45 | M-1 | 45 | — | — | 6,600 | 1.5 |
| Example 2-2 | | | | | | | | | | | |
| Synthesis | A-3 | X-3 | 10 | M-13 | 45 | M-1 | 45 | — | — | 7,000 | 1.4 |
| Example 2-3 | | | | | | | | | | | |
| Synthesis | A-4 | X-4 | 10 | M-13 | 45 | M-1 | 45 | — | — | 6,400 | 1.5 |
| Example 2-4 | | | | | | | | | | | |
| Synthesis | A-5 | X-5 | 10 | M-13 | 45 | M-1 | 45 | — | — | 6,500 | 1.5 |
| Example 2-5 | | | | | | | | | | | |
| Synthesis | A-6 | X-6 | 10 | M-13 | 45 | M-1 | 45 | — | — | 6,300 | 1.5 |
| Example 2-6 | | | | | | | | | | | |
| Synthesis | A-7 | X-7 | 10 | M-13 | 45 | M-1 | 45 | — | — | 6,500 | 1.5 |
| Example 2-7 | | | | | | | | | | | |
| Synthesis | A-8 | X-8 | 10 | M-13 | 45 | M-1 | 45 | — | — | 6,900 | 1.4 |
| Example 2-8 | | | | | | | | | | | |
| Synthesis | A-9 | X-9 | 10 | M-13 | 45 | M-1 | 45 | — | — | 7,000 | 1.4 |
| Example 2-9 | | | | | | | | | | | |
| Synthesis | A-10 | X-1 | 10 | M-13 | 45 | M-2 | 45 | — | — | 6,200 | 1.5 |
| Example 2-10 | | | | | | | | | | | |
| Synthesis | A-11 | X-1 | 10 | M-13 | 45 | M-3 | 45 | — | — | 6,500 | 1.5 |
| Example 2-11 | | | | | | | | | | | |
| Synthesis | A-12 | X-1 | 10 | M-13 | 45 | M-4 | 45 | — | — | 6,800 | 1.5 |
| Example 2-12 | | | | | | | | | | | |
| Synthesis | A-13 | X-1 | 10 | M-13 | 45 | M-5 | 45 | — | — | 7,100 | 1.4 |
| Example 2-13 | | | | | | | | | | | |
| Synthesis | A-14 | X-1 | 10 | M-13 | 45 | M-6 | 45 | — | — | 6,200 | 1.5 |
| Example 2-14 | | | | | | | | | | | |
| Synthesis | A-15 | X-1 | 10 | M-13 | 45 | M-8 | 45 | — | — | 6,600 | 1.4 |
| Example 2-15 | | | | | | | | | | | |
| Synthesis | A-16 | X-1 | 10 | M-13 | 45 | M-9 | 45 | — | — | 6,200 | 1.5 |
| Example 2-16 | | | | | | | | | | | |
| Synthesis | A-17 | X-1 | 10 | M-13 | 45 | M-10 | 45 | — | — | 5,900 | 1.5 |
| Example 2-17 | | | | | | | | | | | |
| Synthesis | A-18 | X-1 | 10 | M-13 | 45 | M-11 | 45 | — | — | 6,600 | 1.5 |
| Example 2-18 | | | | | | | | | | | |
| Synthesis | A-19 | X-1 | 10 | M-13 | 45 | M-12 | 45 | — | — | 7,100 | 1.4 |
| Example 2-19 | | | | | | | | | | | |
| Synthesis | A-20 | X-1 | 10 | M-13/M-14 | 25/20 | M-1 | 45 | — | — | 6,700 | 1.5 |
| Example 2-20 | | | | | | | | | | | |
| Synthesis | A-21 | X-1 | 10 | M-13/M-15 | 25/20 | M-1 | 45 | — | — | 5,800 | 1.5 |
| Example 2-21 | | | | | | | | | | | |
| Synthesis | A-22 | X-1 | 10 | M-13/M-16 | 25/20 | M-1 | 45 | — | — | 5,900 | 1.5 |
| Example 2-22 | | | | | | | | | | | |
| Synthesis | A-23 | X-1 | 5 | M-13 | 45 | M-1 | 50 | — | — | 6,200 | 1.5 |
| Example 2-23 | | | | | | | | | | | |
| Synthesis | A-24 | X-1 | 15 | M-13 | 45 | M-1 | 40 | — | — | 6,600 | 1.5 |
| Example 2-24 | | | | | | | | | | | |
| Synthesis | CA-1 | — | — | M-13 | 45 | M-1 | 45 | M-7 | 10 | 6,000 | 1.5 |
| Example 2-25 | | | | | | | | | | | |
| Synthesis | CA-2 | — | — | M-13 | 45 | M-1 | 55 | — | — | 6,300 | 1.5 |
| Example 2-26 | | | | | | | | | | | |

### Synthesis of Polymer (F)

Polymer (F-1) as the polymer (F) was synthesized in accordance with the following method. For synthesis of the polymer (F), the monomer (M-1) and the monomer (M-4), as well as compounds (hereinafter, may be also referred to as “monomers (M-17) to (M-18)” represented by the following formulae (M-17) to (M-18) were used.

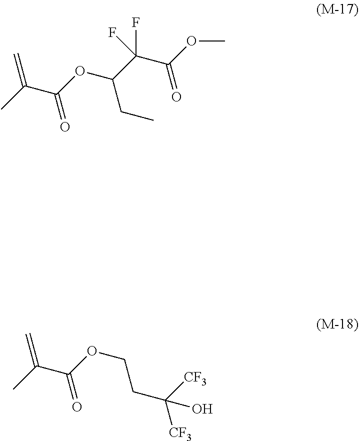

### Synthesis Example 3-1: Synthesis of Polymer (F-1)

The monomer (M-1) and the monomer (M-17) were dissolved in 2-butanone (200 parts by mass) such that the molar ratio became 30/70. A monomer solution was prepared by adding AIBN (5 mol % with respect to the total monomers) thereto as an initiator. Meanwhile, into an empty reaction vessel was charged 2-butanone (100 parts by mass), and purging with nitrogen was performed for 30 min. The internal temperature of the reaction vessel was elevated to 80° C., and the monomer solution was added dropwise thereto over 3 hrs with stirring. After completion of the dropwise addition, stirring was performed at 80° C. for 3 hrs further. The polymerization solution was cooled to no greater than 30° C., and then the solvent was replaced with acetonitrile (400 parts by mass). Subsequently, an operation of adding hexane (100 parts by mass) to a resulting solution, stirring, and recovering an acetonitrile layer was performed three times. The solvent was replaced with propylene glycol monomethyl ether acetate to give a solution of the polymer (F-1) with a favorable yield. The Mw of the polymer (F-1) was 5,900, and the Mw/Mn was 1.7.

### Synthesis Example 3-2: Synthesis of Polymer (F-2)

The polymer (F-2) was synthesized by a similar operation to that of Synthesis Example 3-1, except that each monomer of the type and in the proportion shown in Table 2 below was used.

Types and usage proportions of the monomers that give each structural unit in the polymers obtained in Synthesis Examples 3-1 to 3-2, as well as the Mw and the Mw/Mn thereof, are shown in Table 2 below.

TABLE 2

| | | Monomer that | | Monomer that | | | |
|---|---|---|---|---|---|---|---|
| | | gives structural | | gives other | | | |
| | | unit (f) | | structural unit | | | |
| | [F] | | blending | | blending | | |
| | Poly- | | amount | | amount | | Mw/ |
| | mer | type | (mol %) | type | (mol %) | Mw | Mn |
| Synthesis | F-1 | M-17 | 70 | M-1 | 30 | 5,900 | 1.7 |
| Example | | | | | | | |
| 3-1 | | | | | | | |
| Synthesis | F-2 | M-18 | 65 | M-4 | 35 | 6,000 | 1.7 |
| Example | | | | | | | |
| 3-2 | | | | | | | |

### Preparation of Radiation-Sensitive Resin Composition

The acid generating agent (B), the acid diffusion control agent (C), and the organic solvent (D) used in preparation of the radiation-sensitive resin composition are shown below. In the following Examples and Comparative Examples, unless otherwise specified particularly, the term “parts by mass” means a value, provided that the mass of the polymer (A) used was 100 parts by mass, and the term “mol %” means a value, provided that the mol number of the acid generating agent (B) used was 100 mol %.

### (B) Acid Generating Agent

Compounds (hereinafter, may be also referred to as “acid generating agents (CB-1) and (B-1) to (B-7)”) represented by the following formulae (CB-1) and (B-1) to (B-7) were used as the acid generating agent (B). The acid generating agents (B-1) to (B-7) correspond to the compound (Z).

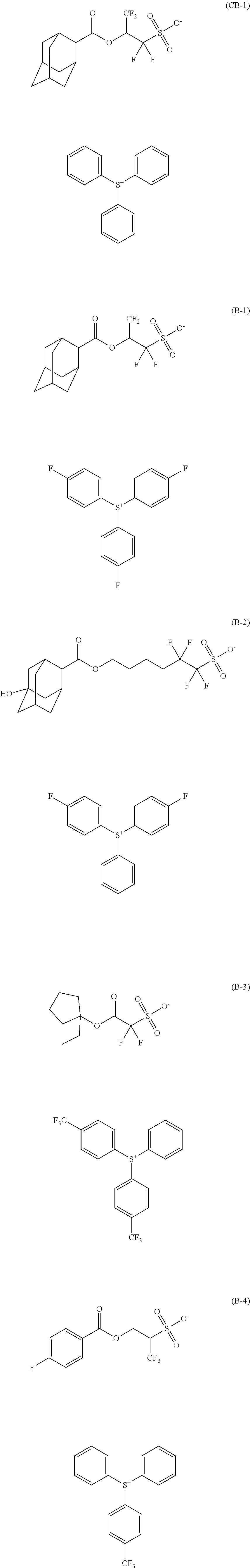

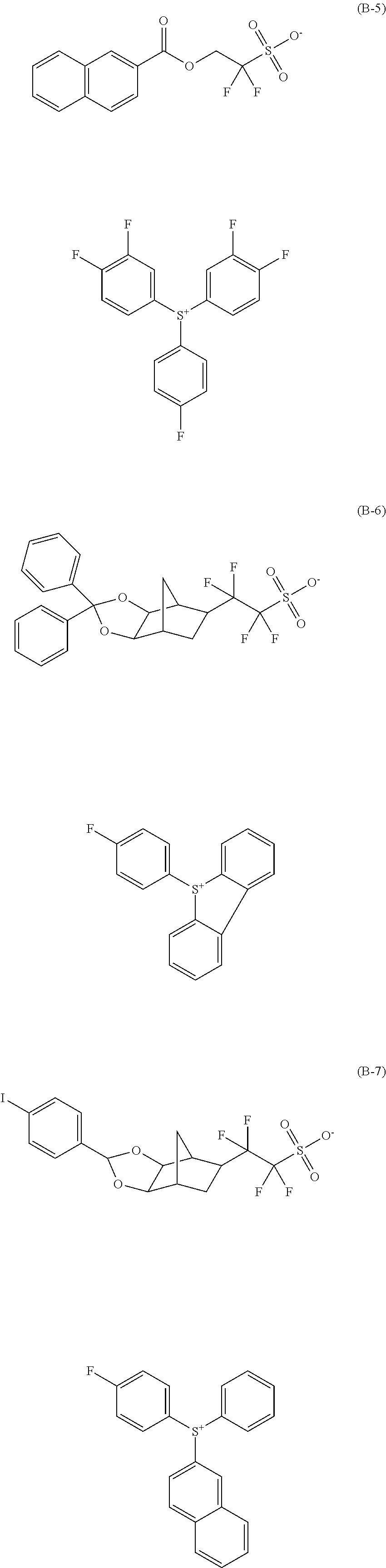 [SMILES: O=C(OCC(F)(F)S(=O)(=O)[O-])c1ccc2ccccc2c1 ; Fc1ccc([S+](c2ccc(F)c(F)c2)c2ccc(F)c(F)c2)cc1 ; O=S(=O)([O-])C(F)(F)C(F)(F)C1CC2CC1C1OC(c3ccccc3)(c3ccccc3)OC21 ; Fc1ccc(-[s+]2c3ccccc3c3ccccc32)cc1 ; O=S(=O)([O-])C(F)(F)C(F)(F)C1CC2CC1C1OC(c3ccc(I)cc3)OC21 ; Fc1ccc([S+](c2ccccc2)c2ccc3ccccc3c2)cc1]

### (C) Acid Diffusion Control Agent

Compounds (hereinafter, may be also referred to as “acid diffusion control agents (C-1) to (C-6)”) represented by the following formulae (CC-1) and (C-1) to (C-6) were used as the acid diffusion control agent (C). The acid diffusion control agents (C-1) to (C-6) correspond to the compound (Z).

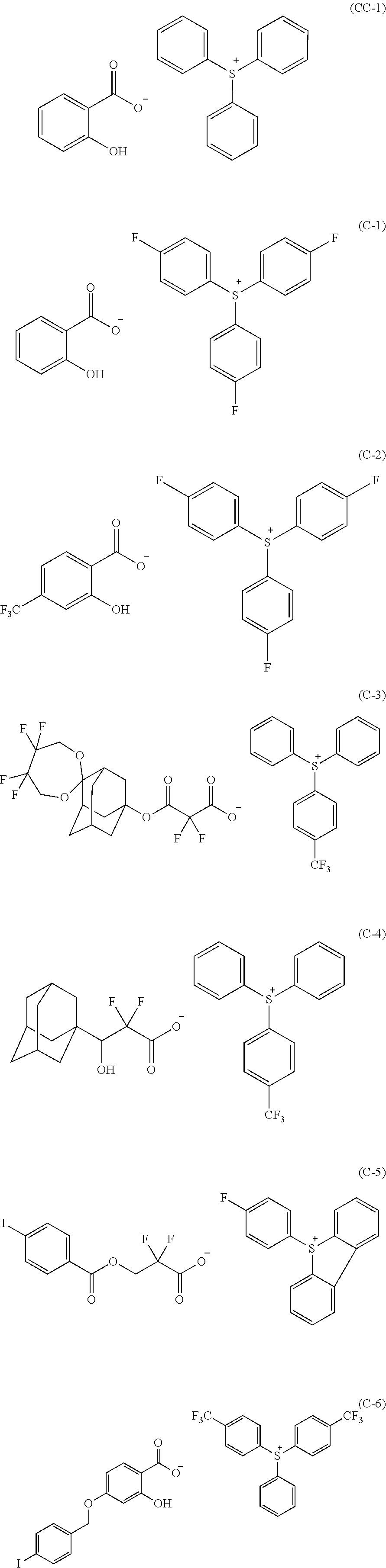

### (D) Organic Solvent

The following organic solvents were used as the organic solvent (D).
(D-1): propylene glycol monomethyl ether acetate
(D-2): propylene glycol monomethyl ether

### Example 1: Preparation of Radiation-Sensitive Resin Composition (R-1)

One hundred parts by mass of (A-1) as the polymer (A), 20 parts by mass of (B-1) as the acid generating agent (B), (C-1) as the acid diffusion control agent (C) at an amount of 35 mol % with respect to (B-1), 5 parts by mass of (F-1) as the polymer (F), and 4,000 parts by mass of (D-1) and 1,600 parts by mass of (D-2) as the organic solvent (D) were admixed. A mix liquid thus obtained was filtered through a filter having a pore size of 0.2 m to prepare the radiation-sensitive resin composition (R-1).

### Examples 2 to 39 and Comparative Examples 1 to 4: Preparation of Radiation-Sensitive Resin Compositions (R-2) to (R-39) and (CR-1) to (CR-4)

Radiation-sensitive resin compositions (R-2) to (R-39) and (CR-1) to (CR-4) were prepared similarly to Example 1, except that each component of the following type and in the following content shown in Table 3 below was used. In the Table 3 below, “-” indicates that the corresponding component was not used.

TABLE 3

| | | | | (B) Acid | | (C) Acid | | | | | |
|---|---|---|---|---|---|---|---|---|---|---|---|
| | Radiation- | (A) Polymer | | generating agent | | diffusion | | (F) Polymer | | (D) Organic solvent | |
| | sensitive | | content | | content | control agent | | | content | | content |
| | resin | | (parts | | (parts | | content | | (parts | | (parts |
| | composition | type | by mass) | type | by mass) | type | (mol %) | type | by mass) | type | by mass) |
| Example 1 | R-1 | A-1 | 100 | B-1 | 20 | C-1 | 35 | F-1 | 5 | D-1/D-2 | 4,000/1,600 |
| Example 2 | R-2 | A-2 | 100 | B-1 | 20 | C-1 | 35 | F-1 | 5 | D-1/D-2 | 4,000/1,600 |
| Example 3 | R-3 | A-3 | 100 | B-1 | 20 | C-1 | 35 | F-1 | 5 | D-1/D-2 | 4,000/1,600 |
| Example 4 | R-4 | A-4 | 100 | B-1 | 20 | C-1 | 35 | F-1 | 5 | D-1/D-2 | 4,000/1,600 |
| Example 5 | R-5 | A-5 | 100 | B-1 | 20 | C-1 | 35 | F-1 | 5 | D-1/D-2 | 4,000/1,600 |
| Example 6 | R-6 | A-6 | 100 | B-1 | 20 | C-1 | 35 | F-1 | 5 | D-1/D-2 | 4,000/1,600 |
| Example 7 | R-7 | A-7 | 100 | B-1 | 20 | C-1 | 35 | F-1 | 5 | D-1/D-2 | 4,000/1,600 |
| Example 8 | R-8 | A-8 | 100 | B-1 | 20 | C-1 | 35 | F-1 | 5 | D-1/D-2 | 4,000/1,600 |
| Example 9 | R-9 | A-9 | 100 | B-1 | 20 | C-1 | 35 | F-1 | 5 | D-1/D-2 | 4,000/1,600 |
| Example 10 | R-10 | A-10 | 100 | B-1 | 20 | C-1 | 35 | F-1 | 5 | D-1/D-2 | 4,000/1,600 |
| Example 11 | R-11 | A-11 | 100 | B-1 | 20 | C-1 | 35 | F-1 | 5 | D-1/D-2 | 4,000/1,600 |
| Example 12 | R-12 | A-12 | 100 | B-1 | 20 | C-1 | 35 | F-1 | 5 | D-1/D-2 | 4,000/1,600 |
| Example 13 | R-13 | A-13 | 100 | B-1 | 20 | C-1 | 35 | F-1 | 5 | D-1/D-2 | 4,000/1,600 |
| Example 14 | R-14 | A-14 | 100 | B-1 | 20 | C-1 | 35 | F-1 | 5 | D-1/D-2 | 4,000/1,600 |
| Example 15 | R-15 | A-15 | 100 | B-1 | 20 | C-1 | 35 | F-1 | 5 | D-1/D-2 | 4,000/1,600 |
| Example 16 | R-16 | A-16 | 100 | B-1 | 20 | C-1 | 35 | F-1 | 5 | D-1/D-2 | 4,000/1,600 |
| Example 17 | R-17 | A-17 | 100 | B-1 | 20 | C-1 | 35 | F-1 | 5 | D-1/D-2 | 4,000/1,600 |
| Example 18 | R-18 | A-18 | 100 | B-1 | 20 | C-1 | 35 | F-1 | 5 | D-1/D-2 | 4,000/1,600 |
| Example 19 | R-19 | A-19 | 100 | B-1 | 20 | C-1 | 35 | F-1 | 5 | D-1/D-2 | 4,000/1,600 |
| Example 20 | R-20 | A-20 | 100 | B-1 | 20 | C-1 | 35 | F-1 | 5 | D-1/D-2 | 4,000/1,600 |
| Example 21 | R-21 | A-21 | 100 | B-1 | 20 | C-1 | 35 | F-1 | 5 | D-1/D-2 | 4,000/1,600 |
| Example 22 | R-22 | A-22 | 100 | B-1 | 20 | C-1 | 35 | F-1 | 5 | D-1/D-2 | 4,000/1,600 |
| Example 23 | R-23 | A-23 | 100 | B-1 | 20 | C-1 | 35 | F-1 | 5 | D-1/D-2 | 4,000/1,600 |
| Example 24 | R-24 | A-24 | 100 | B-1 | 20 | C-1 | 35 | F-1 | 5 | D-1/D-2 | 4,000/1,600 |
| Example 25 | R-25 | A-1 | 100 | CB-1 | 20 | C-1 | 35 | F-1 | 5 | D-1/D-2 | 4,000/1,600 |
| Example 26 | R-26 | A-1 | 100 | B-2 | 20 | C-1 | 35 | F-1 | 5 | D-1/D-2 | 4,000/1,600 |
| Example 27 | R-27 | A-1 | 100 | B-3 | 20 | C-1 | 35 | F-1 | 5 | D-1/D-2 | 4,000/1,600 |
| Example 28 | R-28 | A-1 | 100 | B-4 | 20 | C-1 | 35 | F-1 | 5 | D-1/D-2 | 4,000/1,600 |
| Example 29 | R-29 | A-1 | 100 | B-5 | 20 | C-1 | 35 | F-1 | 5 | D-1/D-2 | 4,000/1,600 |
| Example 30 | R-30 | A-1 | 100 | B-6 | 20 | C-1 | 35 | F-1 | 5 | D-1/D-2 | 4,000/1,600 |
| Example 31 | R-31 | A-1 | 100 | B-7 | 20 | C-1 | 35 | F-1 | 5 | D-1/D-2 | 4,000/1,600 |
| Example 32 | R-32 | A-1 | 100 | B-1 | 20 | CC-1 | 35 | F-1 | 5 | D-1/D-2 | 4,000/1,600 |
| Example 33 | R-33 | A-1 | 100 | B-1 | 20 | C-2 | 35 | F-1 | 5 | D-1/D-2 | 4,000/1,600 |
| Example 34 | R-34 | A-1 | 100 | B-1 | 20 | C-3 | 35 | F-1 | 5 | D-1/D-2 | 4,000/1,600 |
| Example 35 | R-35 | A-1 | 100 | B-1 | 20 | C-4 | 35 | F-1 | 5 | D-1/D-2 | 4,000/1,600 |
| Example 36 | R-36 | A-1 | 100 | B-1 | 20 | C-5 | 35 | F-1 | 5 | D-1/D-2 | 4,000/1,600 |
| Example 37 | R-37 | A-1 | 100 | B-1 | 20 | C-6 | 35 | F-1 | 5 | D-1/D-2 | 4,000/1,600 |
| Example 38 | R-38 | A-1 | 100 | B-1 | 20 | C-1 | 35 | F-2 | 5 | D-1/D-2 | 4,000/1,600 |
| Example 39 | R-39 | A-1 | 100 | B-1 | 20 | C-1 | 35 | — | — | D-1/D-2 | 4,000/1,600 |
| Comparative | CR-1 | CA-1 | 100 | CB-1 | 20 | CC-1 | 35 | F-1 | 5 | D-1/D-2 | 4,000/1,600 |
| Example 1 | | | | | | | | | | | |
| Comparative | CR-2 | CA-1 | 100 | B-1 | 20 | C-1 | 35 | F-1 | 5 | D-1/D-2 | 4,000/1,600 |
| Example 2 | | | | | | | | | | | |
| Comparative | CR-3 | CA-2 | 100 | CB-1 | 20 | CC-1 | 35 | F-1 | 5 | D-1/D-2 | 4,000/1,600 |
| Example 3 | | | | | | | | | | | |
| Comparative | CR-4 | CA-2 | 100 | B-1 | 20 | C-1 | 35 | F-1 | 5 | D-1/D-2 | 4,000/1,600 |
| Example 4 | | | | | | | | | | | |
| Comparative | CR-5 | A-1 | 100 | CB-1 | 20 | CC-1 | 35 | F-1 | 5 | D-1/D-2 | 4,000/1,600 |
| Example 5 | | | | | | | | | | | |

### Evaluations

Using each radiation-sensitive resin composition prepared as described above, the sensitivity, the CDU performance, and the ability to inhibit development defects were evaluated in accordance with the following methods. The results of the evaluations are shown in Table 4 below.

### Sensitivity

Using a spin coater (“CLEAN TRACK ACT 12,” available from Tokyo Electron Limited), the radiation-sensitive resin compositions prepared as described above were each applied on a surface of a 12-inch silicon wafer with an underlayer film (“AL412,” available from Brewer Science, Inc.) having an average film thickness of 20 nm being formed thereon, and PB (prebaking) was conducted at 100° C. for 60 sec. Thereafter, by cooling at 23° C. for 30 sec, a resist film having an average thickness of 30 nm was formed. The resist film was irradiated with EUV using an EUV scanner (model “NXE3300”, available from ASML Co., with NA of 0.33 under an illumination condition of Conventional s=0.89). The resist film was subjecting to PEB (post-exposure baking) at 100° C. for 60 sec and then developed at 23° C. for 30 sec using a 2.38% by mass aqueous solution of TMAH to form a positive-tone resist pattern with 50 nm pitch and a 25 nm contact hole pattern. An exposure dose at which the 25 nm contact hole pattern was formed was defined as an optimum exposure dose, and this optimum exposure dose was adopted as sensitivity (mJ/cm²). The sensitivity being smaller in value indicates superiority. The sensitivity was evaluated to be: “A” (extremely favorable) in a case of being less than 34 mJ/cm²; “B” (favorable) in a case of being no less than 34 mJ/cm² and no greater than 36 mJ/cm²; and “C” (unfavorable) in a case of being greater than 36 mJ/cm².

### CDU Performance

An irradiation was performed at the optimum exposure dose determined in the above section “Sensitivity”, and a 25 nm contact hole pattern was formed similarly to that described above. The pattern of the resist pattern formed was observed from above by using a scanning electron microscope (“CG-5000,” available from Hitachi High-Technologies Corporation). Variance in hole diameters was measured at a total of 600 points, a 3 Sigma value was determined from a distribution of the measurement values, and this 3 Sigma value was adopted as the CDU performance (nm). Variance (3σ) of the dimensions was determined, and this was adopted as CDU (nm). The CDU being smaller in value indicates more favorable CDU performance, revealing less variance of the hole diameters in greater ranges. The CDU performance was evaluated to be: “A” (extremely favorable) in a case of the CDU value being less than 2.4 nm; “B” (favorable) in a case of the CDU value being no less than 2.4 nm and no greater than 2.6 nm; and “C” (unfavorable) in a case of the CDU value being greater than 2.6 nm.

### Ability to Inhibit Development Defects

An irradiation was performed at the optimum exposure dose determined in the above section “Sensitivity”, and a 25 nm contact hole pattern was formed similarly to that described above and adopted as a wafer for testing defects. The number of defects on this wafer for testing defects was counted using a defect-testing apparatus (“KLA2810”, manufactured by KLA-Tencor). Furthermore, the defects measured were categorized into: defects assessed to derive from the resist film; and foreign matter derived from externally. The number of defects after development was evaluated to be: “A” (extremely favorable) in a case in which the number of defects assessed to be derived from the resist film was less than 40; “B” (favorable) in a case in which this number was no less than 40 and no greater than 50; and “C” (unfavorable) in a case in which this number was greater than 50.

TABLE 4

| | | | | Ability to |
|---|---|---|---|---|
| | | | | inhibit |
| | Radiation-sensitive | | | development |
| | resin composition | Sensitivity | CDU | defects |
| Example 1 | R-1 | A | B | A |
| Example 2 | R-2 | A | B | A |
| Example 3 | R-3 | A | A | A |
| Example 4 | R-4 | A | A | B |
| Example 5 | R-5 | A | B | B |
| Example 6 | R-6 | A | B | A |
| Example 7 | R-7 | B | A | A |
| Example 8 | R-8 | A | B | B |
| Example 9 | R-9 | A | A | A |
| Example 10 | R-10 | A | B | A |
| Example 11 | R-11 | B | B | A |
| Example 12 | R-12 | A | A | B |
| Example 13 | R-13 | A | A | A |
| Example 14 | R-14 | A | A | B |
| Example 15 | R-15 | A | B | A |
| Example 16 | R-16 | A | A | B |
| Example 17 | R-17 | A | A | A |
| Example 18 | R-18 | B | A | B |
| Example 19 | R-19 | A | A | B |
| Example 20 | R-20 | A | A | A |
| Example 21 | R-21 | A | A | A |
| Example 22 | R-22 | A | A | A |
| Example 23 | R-23 | A | B | B |
| Example 24 | R-24 | B | A | B |
| Example 25 | R-25 | A | B | A |
| Example 26 | R-26 | B | A | A |
| Example 27 | R-27 | A | B | A |
| Example 28 | R-28 | A | B | B |
| Example 29 | R-29 | A | A | B |
| Example 30 | R-30 | A | B | A |
| Example 31 | R-31 | A | A | B |
| Example 32 | R-32 | A | B | A |
| Example 33 | R-33 | B | A | B |
| Example 34 | R-34 | A | B | B |
| Example 35 | R-35 | B | A | A |
| Example 36 | R-36 | A | A | B |
| Example 37 | R-37 | A | A | B |
| Example 38 | R-38 | A | B | A |
| Example 39 | R-39 | B | B | B |
| Comparative | CR-1 | C | C | C |
| Example 1 | | | | |
| Comparative | CR-2 | C | C | C |
| Example 2 | | | | |
| Comparative | CR-3 | C | C | C |
| Example 3 | | | | |
| Comparative | CR-4 | C | C | C |
| Example 4 | | | | |
| Comparative | CR-5 | C | C | C |
| Example 5 | | | | |

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive resin composition comprising:
a first polymer, solubility of which in a developer solution is capable of being altered by an action of an acid, the first polymer comprising:
a first structural unit comprising a partial structure obtained by substituting a hydrogen atom of a carboxy group, a phenolic hydroxy group, or an amide group with a group represented by formula (1); and
a second structural unit comprising a phenolic hydroxy group; and
a compound comprising:
a monovalent radiation-sensitive onium cation comprising an aromatic ring obtained by substituting at least one hydrogen atom with a fluorine atom or a fluorine atom-containing group; and
a monovalent organic acid anion, 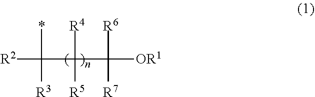
wherein, in the formula (1),
R¹ represents a hydrogen atom or a monovalent organic group having 1 to 20 carbon atoms;
R², R³, one or a plurality of R⁴s, one or a plurality of R⁵s, R⁶, and R⁷ each independently represent a substituted or unsubstituted monovalent hydrocarbon group having 1 to 20 carbon atoms, and optionally two groups among R², R³, one or a plurality of R⁴s, one or a plurality of R⁵s, R⁶, and R⁷ taken together represent an aliphatic ring having 4 to 20 ring atoms together with the carbon atom or the carbon chain to which the two groups bond, wherein in a case in which R⁶ or R⁷ represents the substituted monovalent hydrocarbon group having 1 to 20 carbon atoms, the hydrocarbon group comprises at least one hydrogen atom;
n is an integer of 0 to 5; and
* denotes a site of bonding to an ethereal oxygen atom of the carboxy group, an oxygen atom of the phenolic hydroxy group, or a nitrogen atom of the amide group.

2. The radiation-sensitive resin composition according to claim 1, wherein the radiation-sensitive onium cation is represented by formula (2-1) or formula (2-2): 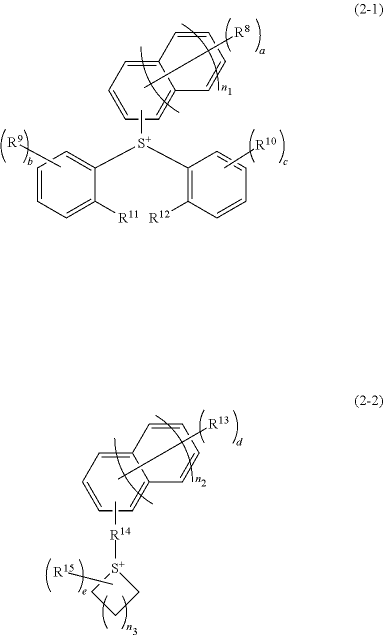
wherein, in the formula (2-1),
a is an integer of 0 to 7, b is an integer of 0 to 4, and c is an integer of 0 to 4, wherein a sum of a, b, and c is no less than 1;
R⁸, R⁹, and R¹⁰ each independently represent a halogen atom, a hydroxy group, a nitro group, or a monovalent organic group having 1 to 20 carbon atoms, wherein
at least one of R⁸, R⁹, and R¹⁰ represents a fluorine atom or a monovalent fluorinated hydrocarbon group having 1 to 10 carbon atoms,
in a case in which a is no less than 2, a plurality of R⁸s are identical or different from each other,
in a case in which b is no less than 2, a plurality of R⁹s are identical or different from each other, and
in a case in which c is no less than 2, a plurality of R¹⁰s are identical or different from each other;
R¹¹ and R¹² each independently represent a hydrogen atom, a fluorine atom, or a monovalent fluorinated hydrocarbon group having 1 to 10 carbon atoms, or R¹¹ and R¹² taken together represent a single bond; and
n₁ is 0 or 1, and
in the formula (2-2),
d is an integer of 1 to 7 and e is an integer of 0 to 10,
wherein
in a case in which d is 1, R¹³ represents a fluorine atom or a monovalent fluorinated hydrocarbon group having 1 to 10 carbon atoms,
in a case in which d is no less than 2, a plurality of R¹³s are identical or different from each other, and each R¹³ represents a halogen atom, a hydroxy group, a nitro group, or a monovalent organic group having 1 to 20 carbon atoms, wherein at least one of the plurality of R¹³s represents a fluorine atom or a monovalent fluorinated hydrocarbon group having 1 to 10 carbon atoms;
R¹⁴ represents a single bond or a divalent organic group having 1 to 20 carbon atoms;
R¹⁵ represents a halogen atom, a hydroxy group, a nitro group, or a monovalent organic group having 1 to 20 atoms, wherein in a case in which e is no less than 2, a plurality of R¹⁵s are identical or different from each other;
n₂ is 0 or 1; and
n₃ is an integer of 0 to 3.

3. The radiation-sensitive resin composition according to claim 1, wherein the first structural unit is represented by formulae (3-1) to (3-3): 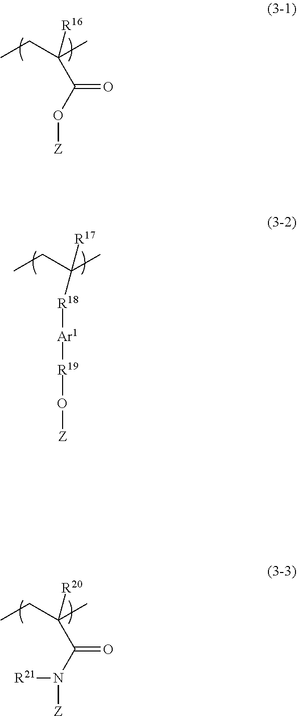
wherein, in the formulae (3-1) to (3-3), Z represents the group represented by the formula (1),
in the formula (3-1), R¹⁶ represents a hydrogen atom, a fluorine atom, a methyl group, or a trifluoromethyl group,
in the formula (3-2), R¹⁷ represents a hydrogen atom or a methyl group; R¹⁸ represents a single bond, an oxygen atom, —COO—, or —CONH—; Ar¹ represents a group obtained by removing two hydrogen atoms from a substituted or unsubstituted aromatic hydrocarbon ring having 6 to 30 ring atoms; and R¹⁹ represents a single bond or —CO—, and
in the formula (3-3), R²⁰ represents a hydrogen atom, a fluorine atom, a methyl group, or a trifluoromethyl group; and R²¹ represents a hydrogen atom or a monovalent organic group having 1 to 20 carbon atoms.

4. The radiation-sensitive resin composition according to claim 1, further comprising a second polymer having a percentage content of fluorine atoms being higher than a percentage content of fluorine atoms of the first polymer.

5. The radiation-sensitive resin composition according to claim 1, wherein R¹ in the formula 1 represents a hydrogen atom.

6. The radiation-sensitive resin composition according to claim 1, wherein n in the formula (1) is 0 or 1.

7. A method of forming a resist pattern, the method comprising:
applying the radiation-sensitive resin composition according to claim 1 directly or indirectly on a substrate to form a resist film;
exposing the resist film; and
developing the resist film exposed.
